(19) United States
(12) Patent Application Publication
(10) Pub. No.: US 2022/0393091 A1
(43) Pub. Date: Dec. 8, 2022

(54) SUPERCONDUCTING QUBITS BASED ON TANTALUM

(71) Applicant: THE TRUSTEES OF PRINCETON UNIVERSITY, Priinceton, NJ (US)

(72) Inventors: Andrew HOUCK, Princeton, NJ (US); Nathalie DE LEON, Princeton, NJ (US); Robert Joseph CAVA, Princeton, NJ (US); Alex PLACE, Princeton, NJ (US); Lila RODGERS, Princeton, NJ (US); Sara SUSSMAN, Princeton, NJ (US); Mattias FITZPATRICK, Princeton, NJ (US); Basil SMITHAM, Princeton, NJ (US)

(21) Appl. No.: 17/776,078

(22) PCT Filed: Nov. 11, 2020
(86) PCT No.: PCT/US2020/060010

§ 371 Date: May 11, 2022

Related U.S. Application Data
(60) Provisional application No. 62/933,758, filed on Nov. 11, 2019.

(51) Int. Cl. H01L 39/24; H01L 39/12

(52) U.S. Cl. CPC H01L 39/2493; H01L 39/12; B82Y 10/00

(57) ABSTRACT

Methods, devices, and systems are described for forming a superconducting qubit. An example device may comprise a substrate having a first surface and a patterned layer adjacent the substrate and comprising tantalum in an alpha phase. The patterned layer may comprise at least a part of a structure for storing a quantum state.

### CROSS-REFERENCE TO RELATED APPLICATIONS

This application is related to U.S. Patent Application No. 62/933,758 filed Nov. 11, 2019, which is hereby incorporated by reference for any and all purposes.

### GOVERNMENT SUPPORT CLAUSE

This invention was made with government support under Grant No. DMR1420541 and No. DMR1839199 awarded by the National Science Foundation and support under Grant No. W911NF-19-1-0016 awarded by the U.S. Army Research Office. The government has certain rights in the invention.

### BACKGROUND

The superconducting transmon qubit is a leading platform for quantum computing and quantum science. Building large, useful quantum systems based on transmon qubits will require significant improvements in qubit relaxation and coherence times, which are orders of magnitude shorter than limits imposed by bulk properties of the constituent materials. This indicates that relaxation likely originates from uncontrolled surfaces, interfaces, and contaminants. Previous efforts to improve qubit lifetimes have focused primarily on designs that minimize contributions from surfaces. However, significant improvements in the lifetime of two-dimensional transmon qubits have remained elusive for several years. Thus, there is a need for more better approaches to superconducting qubits.

### SUMMARY

Described herein are methods, devices, and systems for quantum computing. An example device for forming a superconducting qubit may comprise a substrate having a first surface and a patterned layer adjacent the substrate and comprising tantalum in an alpha phase. The patterned layer may form at least a part of a structure for storing a quantum state.

An example method for producing a superconducting qubit may comprise providing a substrate having a first surface and forming a patterned layer adjacent the substrate and comprising tantalum in an alpha phase. The patterned layer may form at least a part of a structure for storing a quantum state.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to limitations that solve any or all disadvantages noted in any part of this disclosure.

Additional advantages will be set forth in part in the description which follows or may be learned by practice. It is to be understood that both the foregoing general description and the following detailed description are exemplary and explanatory only and are not restrictive.

### BRIEF DESCRIPTION OF THE DRAWINGS

The accompanying drawings, which are incorporated in and constitute a part of this specification, illustrate embodiments and together with the description, serve to explain the principles of the methods and systems.

FIG. 1A shows an example device in accordance with the present disclosure.

FIG. 1B shows an example quantum structure comprising tantalum.

FIG. 1C shows a circuit diagram of the example structure coupled to a resonator via a coupling capacitor.

FIG. 1D shows peak T₁ measurement, showing the excited state population Pₑ as a function of delay time Δt.

FIG. 1E shows a four-probe resistance measurement of an example tantalum film consistent with the critical temperature of α-tantalum.

FIG. 2A shows lifetime and decoherence measurements of an example device over time.

FIG. 2B shows a summary of T₁ time series measurements of example devices with optimized processing and packaging.

FIG. 2C shows T_{2,Echo} measurement of an example device fit with a stretched exponential.

FIG. 2D shows T_{2,CPMG} of an example device as a function of the number of gates in a CPMG pulse sequence.

FIG. 3A shows a scanning transmission electron microscope (STEM) image of an example tantalum film, showing single-crystal columns with the growth direction oriented along the [110] axis.

FIG. 3B shows an atomic resolution STEM image of an interface between two columns, viewed from <11̅1> and <001> zone axes respectively. Fourier transforms are shown in the insets.

FIG. 3C shows a STEM image of a horizontal device cross section, showing grain boundaries.

FIG. 3D shows an x-ray photoelectron spectroscopy (XPS) spectrum of a device, exhibiting peaks from tantalum metal and Ta₂O₅.

FIG. 3E shows a high-resolution STEM with integrated differential phase contrast imaging of the interface between the sapphire and tantalum showing epitaxial growth.

FIG. 4A shows an example process for forming a device as disclosed herein.

FIG. 4B shows a qubit fabrication process.

FIG. 5A shows a scanning electron microscope image of tantalum showing surface roughening.

FIG. 5B shows a scanning electron microscope image of tantalum after a piranha etch and an oxygen plasma etch.

FIG. 5C shows a scanning electron microscope image of tantalum after a wet etch.

FIG. 5D shows a scanning electron microscope image of tantalum after employing a thicker photoresist.

FIG. 6A shows an atomic force microscope (AFM) image of sapphire after dicing, strip-ping resist, and solvent cleaning.

FIG. 6B shows an AFM image of sapphire after piranha cleaning and etching.

FIG. 6C shows an XPS of sapphire indicating carbon contaminants on the sapphire surface.

FIG. 6D shows an XPS of sapphire indicating zinc contaminants on the sapphire surface.

FIG. 7A shows an optical microscope image of crystals on sapphire after etching in refluxing sulfuric acid for 30 min.

FIG. 7B shows an AFM image of sapphire surface showing particulate contaminants after etching and piranha cleaning in borosilicate glassware

FIG. 8A shows an image of an example double pad transmon qubit mounted to a printed circuit board.

FIG. 8B shows an image of an example Xmon qubit mounted to a printed circuit board.

FIG. 8C shows a close-up, false-colored SEM image of the Xmon qubit and coupler.

FIG. 9 shows a schematic of an example measurement electronics and device shielding.

FIG. 10A shows measurement of T₁ over time for Device 3D1.

FIG. 10B shows Fluxonium T₁ as a function of frequency which can be fit to determine the dielectric loss tangent.

FIG. 10C shows dielectric loss tangent.

FIG. 11 shows X-ray diffraction spectrum of a sputtered tantalum film on sapphire.

FIG. 12A Plane-view STEM image showing grain boundaries.

FIG. 12B shows an energy dispersive spectroscopy (EDS) map of the same region shown in FIG. 12A displaying a uniform distribution of tantalum.

FIG. 12C shows an EDS map of the same region shown in FIG. 12A displaying a uniform distribution of oxygen.

FIG. 12D shows an atomic resolution STEM image of the boundaries.

FIG. 12E shows a Fourier transform of the STEM image at a grain boundary indicated by the box region of FIG. 12D, showing a pattern consistent with twinning.

FIG. 12F shows a Fourier transform of the entire image in FIG. 12D shows the rotational symmetries of the grains.

FIG. 13A shows an atomic resolution STEM image showing an amorphous oxide layer about 2-3 nm thick on the tantalum surface.

FIG. 13B shows an angle-resolved XPS measurements of Ta4f region of a fabricated device, offset vertically for clarity.

FIG. 13C shows estimated oxide thickness from XPS as a function of angle between sample and detector.

FIG. 13D shows Ta4f normal incidence XPS data of an example completed device that was solvent cleaned.

FIG. 13E shows Ta4f normal incidence XPS data of an example completed device that was piranha cleaned.

FIG. 13F shows Ta4f normal incidence XPS data of an example completed device that was piranha cleaned.

FIG. 14A shows an atomic resolution integrated differential phase contrast (iDPC) STEM image showing the interface between tantalum and sapphire with the image plane perpendicular to the <100> direction of tantalum.

FIG. 14B shows an atomistic model of the ideal interface for the tantalum column orientation shown in FIG. 14A.

FIG. 14C shows an atomistic model of the ideal interface for the tantalum column orientation shown in FIG. 3E.

FIG. 15A shows T_{2,CPMG} as an increasing number of pulses reduce the qubit's sensitivity to low-frequency noise.

FIG. 15B shows noise power spectral density.

FIG. 16A shows a low T_{2,CPMG} trace from the data in FIG. 2A.

FIG. 16B shows a middle T_{2,CPMG} trace from the data in FIG. 2A.

FIG. 16C shows a long T_{2,CPMG} trace from the data in FIG. 2A.

FIG. 17A show coherence for a 2D transmon with alpha-Ta and high purity substrate.

FIG. 17B shows additional results for a 2D transmon with alpha-Ta and high purity substrate.

FIG. 18A shows lifetime data for an example transmon device.

FIG. 18B shows additional data over time for the example transmon device.

FIG. 18C shows coherence data for another example transmon device.

FIG. 18D shows additional coherence data for another example transmon device.

FIG. 18E shows data for yet another example transmon device.

FIG. 18F shows additional data for yet another example transmon device.

FIG. 19A shows XPS results of sapphire after performing a piranha 2:1 for 20 minutes.

FIG. 19B shows results after applying sulfuric acid.

FIG. 20A shows results after applying sulfuric acid before annealing.

FIG. 20B shows results after applying sulfuric acid and after annealing.

FIG. 21A shows results after sulfuric acid before annealing.

FIG. 21B shows results after sulfuric acid and after annealing.

FIG. 22A shows a transmission electron microscopy (TEM) image of an alpha-Ta film.

FIG. 22B shows a selected area electron diffraction (SAED) of the alpha-Ta film.

FIG. 22C shows direct imaging the interface between an alpha-Ta film and sapphire with TEM.

### DETAILED DESCRIPTION OF ILLUSTRATIVE EMBODIMENTS

Disclosed herein are devices, methods, and systems for forming superconducting qubits based on tantalum metal. The techniques may also involve the preparation and use of high purity sapphire surfaces. More particularly, disclosed is a device for forming a superconducting qubit that comprises tantalum in the alpha phase as the superconductor (e.g., rather than or in addition to, for example aluminum or niobium, both of which are currently widely deployed technologies). Furthermore, disclosed are methods for cleaning and annealing the underlying sapphire substrate in order to remove contaminants that lead to microwave losses, and to ensure a pristine growth surface for the tantalum film. Also disclosed are methods for removing some carbon contamination that results from fabrication and processing. Through these improvements, one is able to extend qubit lifetimes by one order of magnitude over current devices, and over a factor of two over the global state of the art.

Disclosed herein are materials for the production of reliably long coherence in two-dimensional superconducting qubits, such as transmon qubits. The disclosed approach can also be used to improve coherence of other quantum devices, including fluxonium qubits and 3D transmon qubits. Features of the disclosed approach include the ability to fabricate transmons with relaxation times exceeding 300 μs, and in the vicinity of 200 μs reliably across nearly all devices that were tested.

A qubit is a basic unit of quantum information. A device that forms a qubit allows for the forming for different quantum states to store the quantum information. Superconducting qubits are the primary technology in the industry for bringing commercial quantum computing to fruition. Quantum computing has the potential to revolutionize computation of certain intractable problems, with possible impact in cryptography, optimization, machine learning, finance, and drug discovery.

Superconducting systems typically use aluminum or niobium or, on occasion, nitrides, such as NbTiN, as the metal in their process. Conventional superconducting systems have limited coherence, meaning that quantum information does not last long enough to perform fault tolerant calculations. The techniques disclosed herein for preparing a suitable substrate have likewise not been known to have ever been stated or employed in any system. As described further herein the disclosed techniques have been demonstrated to achieve a factor of two in qubit lifetime over the world's best published devices (which are the result of years of optimization and industry quality fabrication). Coherence is the limiting factor in determining error rates in quantum computing, which is the primary barrier to commercially viable computation. Because the disclosed approach is materials-driven, it is compatible with any existing technology.

Disclosed herein, inter alia, is that a particular phase of tantalum thin films is an excellent material for superconducting quantum computing. Disclosed herein is an underlying substrate, free from surface contaminants and smooth, to present a pristine surface for the growth of the tantalum films. Disclosed herein is device with substantially reduced carbon contamination.

An example tantalum film (e.g., in the alpha phase) may be produced by sputtering-deposition with a substrate (e.g., or other layer on a substrate) at elevated temperature to ensure the proper crystalline phase. The substrate (e.g., or layer on the substrate) may be prepared by an etching process in hot sulfuric acid. The etching process may be followed by a piranha clean, a high temperature anneal, or a combination thereof. Devices may be prepared from the tantalum films by either a dry etch or wet etch process, with carbon removed via a piranha clean and an oxygen plasma descum.

The tantalum deposition may use heating in situ to achieve the correct thin film phase. This may add a small complication to fabrication, but such processing is readily available in commercial instruments.

As disclosed further herein, several example devices have been fabricated that show improvement in qubit lifetimes using the disclosed materials and techniques. Relaxation times of up to 315 μs have been observed in these devices, with consistent times in the vicinity of 200 μs. Typical numbers for academic groups are closer to 50 us, with industry leaders around 100 μs in published results.

The disclosed approach will lead to an immediate improvement in existing quantum computing technology with minimal change to current fabrication processes and device architectures, and therefore should be readily deployable in all current efforts that are based on superconducting qubits.

The examples disclosed herein show that the disclosed techniques allow for two-dimensional transmon qubits (e.g., and other types of qubits) that have both lifetimes and coherence times with dynamical decoupling exceeding 0.3 milliseconds by replacing niobium with tantalum in the device. Increased lifetimes were observed for seventeen devices, indicating that these material improvements are robust, paving the way for higher gate fidelities in multi-qubit processors.

Steady progress in improving gate fidelities for superconducting qubits over the last two decades has enabled key demonstrations of quantum algorithms, quantum error correction, and quantum supremacy. These demonstrations have relied on either improving coherence through microwave engineering to avoid losses associated with surfaces and interfaces and to minimize the effects of thermal noise and quasiparticles, or by realizing fast gates using tunable coupling. By contrast, little progress has been made in addressing the microscopic source of loss and noise in the constituent materials. Specifically, the lifetime (T₁) of the two-dimensional (2D) transmon qubit has not reliably improved beyond 100 μs since 2012, and to date the longest published T₁ is 114 μs, consistent with other recent literature reports.

The lifetimes of current 2D transmons are believed to be limited by microwave dielectric losses. However, the expected loss tangent of the bulk constituent materials should allow for significantly longer lifetimes. For example, high-purity bulk sapphire has a loss tangent less than 10⁻⁹, which would enable T₁ to exceed 30 ms. This suggests that losses are dominated instead by uncontrolled defects at surfaces and interfaces, or by material contaminants. Demonstrated herein are devices and methods that result in significant improvement over the state of the art in 2D transmon qubits. These results can be achieved by using tantalum as the superconductor in the capacitor and microwave resonators, replacing the more commonly used niobium. It is hypothesized that the complicated stoichiometry of oxides at the niobium surface leads to additional microwave loss, and that the insulating oxide of tantalum reduces microwave loss in the device. A time-averaged T₁ exceeding 0.3 ms was in the best device and an average T₁ of 0.23 ms averaged across all devices, a significant improvement over the state of the art.

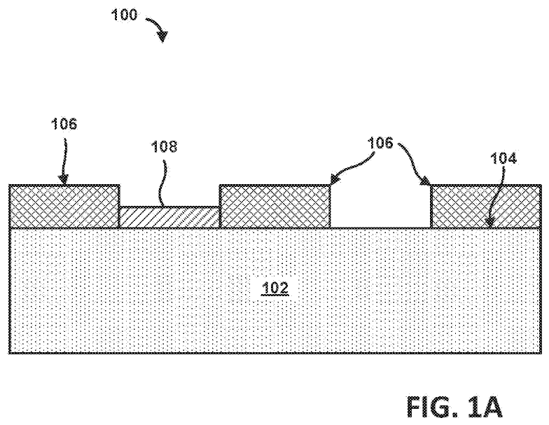

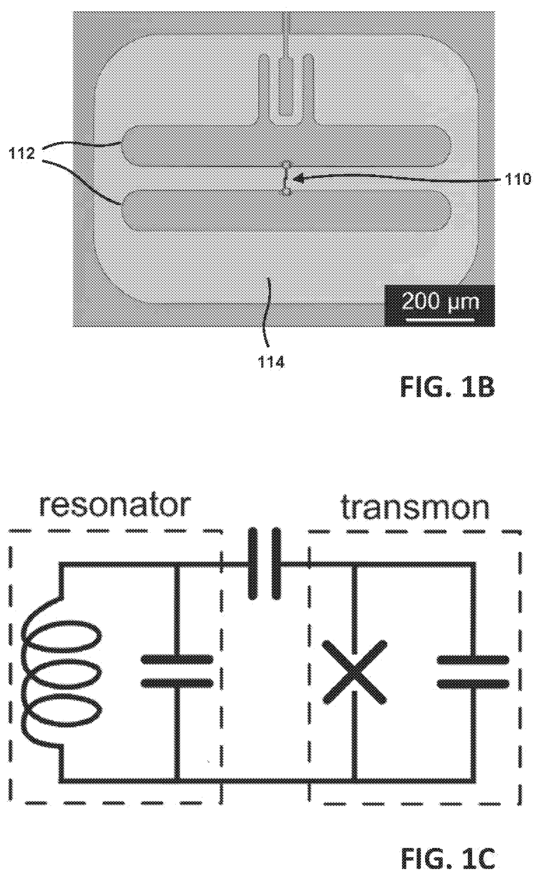

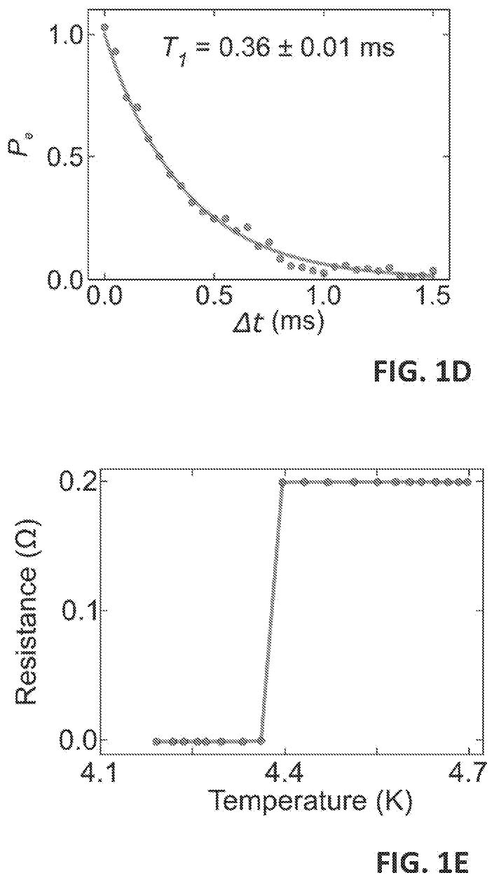

FIG. 1A shows an example device 100 in accordance with the present disclosure. The device 100 may comprise a device for forming a qubit. The device 100 may comprise a superconducting device.

The device 100 may comprise a first layer 102. The first layer 102 may comprise a substrate. The first layer 102 may comprise an insulator. The first layer 102 may comprise sapphire, silicon, any insulator material, or a combination thereof. The first layer 102 may comprise a first surface 104. The first surface 104 may be a treated surface having impurities (e.g., carbon, zinc) removed. The first surface 104 may contain (e.g., or comprise) least one of: less than 6 atomic percent carbon as measured by X-ray photoelectron spectroscopy (XPS) or less than 0.1 atomic percent zinc as measured by X-ray photoelectron spectroscopy (XPS). The first surface 102 may be an atomically smooth surface. The first surface 102 may have an average roughness less than 0.1 nm as measured by atomic force microscopy.

The device 100 may comprise a second layer 106. The second layer 106 may be adjacent the first layer 102. As used herein, the term adjacent when used in relation to a layer can comprise next to, in contact with, above, on top of, below, coupled to, or a combination thereof. The term adjacent can allow for one or more intervening layers between two layers that are adjacent. The terms above, below, and on top of when used in relation to one layer being above, below, or on top of another layer (e.g., or material stack of layers) is specific to the orientation shown in the figures of the present application (e.g., FIG. 1A) in which layers are shown vertically stacked in a vertical direction from the bottom of the figures to the top of the figures. A layer that is above another layer is vertically higher than the other layer according to the orientation shown in the figures (e.g., is shown closer to the top of the figures than the other layer). A layer that is below another layer is vertically lower than the other layer according to the orientation shown in the figures (e.g., is shown closer to the bottom of the figures than another layer). A layer that is on top of another layer is above the other layer and has at least a portion of a bottom surface in contact with at least a portion of a top surface of the other layer. It should be understood that if the layers of an implemented device are rotated to a different orientation than the orientation shown, the layers in the different orientation are still understood to be above, below, or on top of another layer if such relationship applies when oriented in the manner shown in the figures of the present application. The second layer 106 may be in contact with the first surface 104. If any layers exist between the first layer 102 and the second layer 106, the intervening layer may be treated to have the properties of the first surface 104.

The second layer 106 may comprise a patterned layer. The second layer (e.g., the patterned layer) may form at least a part (e.g., or all) of a structure for storing a quantum state. The part of the structure may comprise an electrical component of a circuit configured to form a qubit. The structure (e.g., or the second layer 106) may be free of niobium. A relaxation time of the quantum state may comprise one or more of at least 150 μs, at least 200 μs, or at least 300 μs. The relaxation time of the quantum state may be in a range of one or more of 150 μs to 317 μs or 200 μs to 317 μs. The quantum state may be based on enabling energy levels (e.g., non-harmonic energy levels) for forming qubit states. The structure may be configured to enable forming the energy levels. The structure may comprise one or more of a qubit, a transmon qubit, a X mon qubit, a three-dimensional transmon qubit, a fluxonium qubit, a zero-pi qubit, or a combination thereof.

The second layer 106 (e.g., patterned layer) may form at least a portion of a first circuit component. The second layer 106 (e.g., the patterned layer) may form one or more electrical circuit components configured to store the quantum state. The second layer 106 may comprise tantalum. The tantalum may comprise tantalum in an alpha phase. The tantalum in the alpha phase may comprise tantalum having a body-centered cubic crystal structure. The structure, the first circuit component, and/or the like may comprise tantalum, such as tantalum in the alpha phase.

The device 100 may comprise a third layer 108 (e.g., or one or more additional layers). The third layer 108 may be adjacent the second layer 106, adjacent the first layer 102, or a combination thereof. The third layer 108 have portions patterned in between the patterned portions of the second layer 106. It should be understood that the third layer 108, though shown as between portions of the second layer 106 may be disposed on top of and/or below the second layer 102.

The third layer 108 may comprise a metallic material, a conductive material, and/or the like. The third layer 108 may comprise aluminum, tantalum, tantalum in the alpha phase, a combination thereof, and/or the like. The third layer 108 may form one or more additional electrical components. The second layer 106 (e.g., patterned layer) and the third layer 108 may form an electrical circuit configured to form energy levels for storing the quantum state. The third layer 108 (e.g., or the one or more additional electrical components) may comprise a Josephson junction. The second layer 106, the third layer 108, or a combination thereof may form a plurality of superconducting qubits.

FIGS. 1B-E show an example tantalum-based transmon superconducting qubit. FIG. 1B is an example implementation of the device of FIG. 1A. FIG. 1B shows a false-colored optical micro-scope image of the example transmon qubit. The transmon consists (e.g., or comprises) of a Josephson junction 110 shunted by two large capacitor islands 112 made of tantalum (darker color). The two large capacitor islands 112 are disposed upon a substrate 114. The two large capacitor islands 112 may be the second layer 106 (e.g., patterned layer) of FIG. 1A. The Josephson junction 110 may be the third layer 108 of FIG. 1A.

FIG. 1C shows a corresponding circuit diagram of the transmon qubit coupled to the resonator via a coupling capacitor. FIG. 1D shows peak T₁ measurement, showing the excited state population Pₑ as a function of delay time Δt. Line represents a single exponential fit with a characteristic T₁ time of 0.36±0.01 ms. FIG. 1E shows a Four-probe resistance measurement of the tantalum film showing T_{c}=4.38±0.02 K, consistent with the critical temperature of α-tantalum.

To fabricate qubits, tantalum may be deposited on sapphire substrates by sputtering. During the sputtering the substrate may be heated to ensure growth of the a phase. The substrate may be heated to around 500° C. Photolithography and a wet chemical etch may be used to define a capacitor and resonator of the device. Electron beam lithography and electron beam evaporation of aluminum and aluminum oxide may be used to form Josephson junctions (e.g., see FIG. 1B). Between most key steps of the fabrication process, solvent and piranha cleaning may be used to reduce contamination introduced during fabrication. The transmon may be capacitively coupled to a lithographically-defined cavity (FIG. 1C), allowing to dispersively measure the state of the qubit. To determine T₁, the qubit may be excited with a π-pulse. The decay may be measured over time at a temperature between 9 and 20 mK. In one example device, a peak T₁ of 0.36±0.01 ms was measured, as shown in FIG. 1D. It is verified that the deposited tantalum film is in the BCC a phase by measuring resistance as a function of temperature. The observed superconducting critical temperature (T_{c}) of the example device was around 4.3 K, which is consistent with the intended phase (e.g., FIG. 1E) rather than the tetragonal β phase which has a T_{c} below 1K.

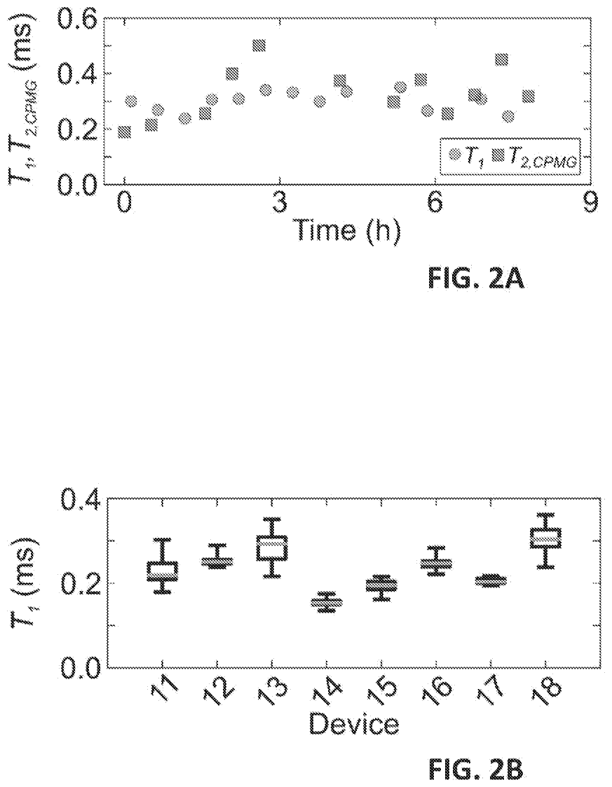

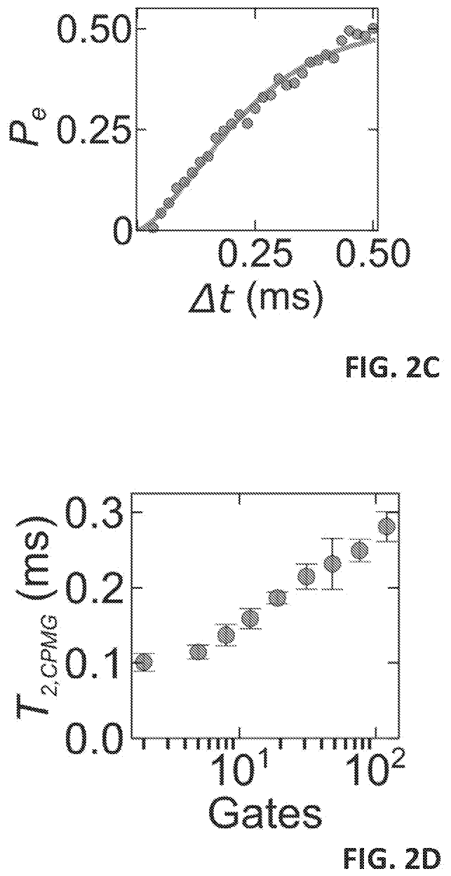

Reproducible, robust enhancement of T₁ was observe across all devices fabricated with this process. FIGS. 2A-D show lifetime and decoherence measurements. FIG. 2A shows measurements of Device 18a over time (fit errors are smaller than the markers). FIG. 2B shows a summary of T₁ time series measurements of all devices with optimized processing and packaging. The yellow line shows the median, while the box spans the middle two quartiles of the data. The whiskers show the extremal measurements. FIG. 2C shows T_{2,Echo} measurement of Device 18a, fit with a stretched exponential. The fit gives T_{2,Echo}=249±4 μs. FIG. 2D shows T_{2,CPMG} of Device 11c as a function of the number of gates in a CPMG pulse sequence.

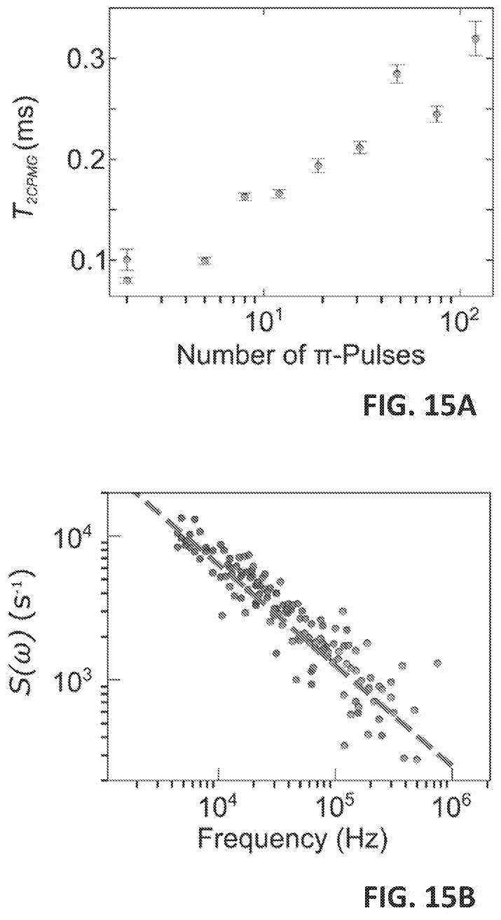

The lifetime of a given qubit fluctuates over time, with a standard deviation of around 7% of the mean (FIG. 2A). Results for eight devices are presented in FIG. 2B, with the time-averaged T₁ ranging from 0.15 ms to 0.30 ms, and an average T₁ of 0.23 ms across all devices, qualitatively exceeding the T₁ of prior 2D transmon devices. The time-averaged coherence time, T_{2,Echo}, in our best device is 0.20±0.03 ms (a trace is shown in FIG. 2C). The coherence time can be extended using a Carr-Purcell-Meiboom-Gill (CPMG) pulse sequence (FIG. 2D). A time-averaged T_{2,CPMG} of 0.38±0.11 ms was achieved in an example device (FIG. 2A). The spectral noise density extracted from dynamical decoupling measurements is consistent with 1/f noise (FIG. 15).

In addition to the eight qubits presented in FIG. 2A-D, data is presented on a total of 23 transmon qubits that were fabricated using different geometries, materials and fabrication processes in Table 1.

TABLE 1

| | Aver- | | | Aver- | Aver- | Aver- | | Al | | | | Opti- | Enclo- | | |
|---|---|---|---|---|---|---|---|---|---|---|---|---|---|---|---|
| | age | Max | | age | age | age | | Coated | Mylar | Pira- | Sap- | mized | sure | Thin | |
| | T₁ | T₁ | Q | T_{2R} | T_{2E} | T_{2,CPMG} | Purcell | Enclo- | Shield- | nha | phire | Wet | Lid | Al | Glos- |
| Device | (μs) | (μs) | (millions) | (μs) | (μs) | (μs) | Filter | sure | ing | Clean | Etch | Etch | Removed | Layer | sary |
| 1a* | 98 ± 2^{†} | 99 | 1.9 | — | — | — | | | | | | | | | Double |
| | | | | | | | | | | | | | | | Pad |
| 1b* | 127 ± 4^{†} | 130 | 2.5 | — | — | — | | | | | | | | | Double |
| | | | | | | | | | | | | | | | Pad |
| 2a | 150 ± 2^{†} | 151 | 4.2 | — | — | — | X | | | | | | | | Double |
| | | | | | | | | | | | | | | | Pad |
| 2b | 157 ± 19 | 179 | 4.4 | 98 ± 8 | 153 ± 12 | — | X | X | X | | | | | | Double |
| | | | | | | | | | | | | | | | Pad |
| 2c | 147 ± 15 | 181 | 4,1 | — | — | — | X | X | X | | | | | | Double |
| | | | | | | | | | | | | | | | Pad |
| 2d* | 171 ± 26 | 223 | 4.8 | — | — | — | X | X | X | | | | | | Double |
| | | | | | | | | | | | | | | | Pad |
| 2a | 146 ± 2^{†} | 151 | 3.6 | — | — | — | X | X | X | | | | | | Double |
| | | | | | | | | | | | | | | | Pad |
| 4a | 200 ± 11 | 219 | 5.3 | 46 ± 4 | 44 ± 7 | — | X | X | X | X | | | | | Double |
| | | | | | | | | | | | | | | | Pad |
| 5a | 146 ± 9 | 169 | 4.4 | 47 ± 5 | 76 ± 7 | — | X | X | X | X | | | | | Double |
| | | | | | | | | | | | | | | | Pad |
| 6a | 58 ± 2^{†} | 58 | 1.8 | — | — | — | X | X | X | X | | | | | Double |
| | | | | | | | | | | | | | | | Pad |
| 7a | 166 ± 1^{†} | 176 | 5.4 | 18 ± 1^{†} | 49 ± 1^{†} | — | X | X | X | X | | | | | Double |
| | | | | | | | | | | | | | | | Pad |
| 7b* | 184 ± 18 | 220 | 6.1 | — | — | — | X | X | X | X | | | | | Double |
| | | | | | | | | | | | | | | | Pad |
| 8a | 135 ± 1^{†} | 135 | 4.5 | — | — | — | X | X | X | X | | | | | Double |
| | | | | | | | | | | | | | | | Pad |
| 9a | 127 ± 1^{†} | 133 | 3.0 | — | — | — | X | X | X | X | X | | | | Double |
| | | | | | | | | | | | | | | | Pad |
| 10a | 139 ± 3^{†} | 139 | 3.9 | — | — | — | X | X | X | X | X | | | | Double |
| | | | | | | | | | | | | | | | Pad |
| 11a | 212 ± 11 | 255 | 5.2 | 41 ± 1 | 53 ± 4 | — | X | X | X | X | X | X | | | Double |
| | | | | | | | | | | | | | | | Pad |
| 11b | 273 ± 27 | 302 | 6.7 | 101 ± 5 | 144 ± 9 | — | X | X | X | X | X | X | X | | Double |
| | | | | | | | | | | | | | | | Pad |
| 11c | 287 ± 19 | 301 | 6.2 | 68 ± 6 | 87 ± 9 | 281 ± 20 | X | X | X | X | X | X | X | | Double |
| | | | | | | | | | | | | | | | Pad |
| 12a | 253 ± 11 | 200 | 6.0 | 53 ± 2 | 71 ± 2 | — | X | X | X | X | X | X | | | Double |
| | | | | | | | | | | | | | | | Pad |
| 12a | 299 ± 35 | 351 | 6.6 | 68 ± 6^{†} | — | — | X | X | X | X | X | X | | | Xmon |
| 12b* | 247 ± 22^{†} | 277 | 5.6 | — | — | — | X | X | X | X | X | X | | | Xmon |
| 14a* | 154 ± 9 | 175 | 4.9 | — | 18 ± 1^{†} | — | X | X | X | X | X | X | | | Xmon |
| 15a | 194 ± 13 | 215 | 4.6 | — | 123 ± 7 | — | X | X | X | X | | X | X | | Double |
| | | | | | | | | | | | | | | | Pad |
| 16a | 247 ± 14 | 282 | 5.5 | — | 62 ± 2 | 122 ± 4^{†} | X | X | X | X | | X | X | | Double |
| | | | | | | | | | | | | | | | Pad |
| 17a | 286 ± 8 | 217 | 5.0 | 58 ± 1^{†} | 78 ± 4 | 93 ± 6^{†} | X | X | X | X | X | X | X | | Double |
| | | | | | | | | | | | | | | | Pad |
| 18a | 383 ± 32 | 362 | 7.1 | 105 ± 3^{†} | 201 ± 28 | 377 ± 111 | X | X | X | X | | X | X | X | Double |
| | | | | | | | | | | | | | | | Pad |
| Nb1* | 23 ± 1^{†} | 23 | 0.4 | — | 42 ± 1^{†} | — | | | | | | | | | Double |
| | | | | | | | | | | | | | | | Pad |
| Nb2 | 79 ± 1^{†} | 82 | 2.0 | — | — | — | X | X | X | | | | | | Double |
| | | | | | | | | | | | | | | | Pad |
| Si1 | 118 ± 2^{†} | 124 | 2.3 | 44 ± 2^{†} | — | — | X | X | X | | | | | | Double |
| | | | | | | | | | | | | | | | Pad |
| SD1 | 283 ± 29 | 239 | 5.2 | 20 ± 1^{†} | 145 ± 17 | — | | | X | | | | | | 3D |
| SD2 | 148 ± 10 | 173 | 3.9 | — | — | — | | | X | X | X | | | | 3D |

Table 1 shows a summary of devices. Measurements of devices with different designs, fabrication procedures, and packaging are shown. Devices labeled “Nb” were made with niobium instead of tantalum (Nb1 was heated to 350° C. then cooled for 20 minutes before deposition, Nb2 was deposited at approximately 500° C.) and all other devices were made from tantalum. Device Si1 was composed of about 200 nm of tantalum deposited on high-resistivity silicon. Devices labeled with the same number but different letters indicate the same qubit measured in different measurement cycles. Entries marked with a “†” had three or fewer repeated measurements, and the reported errors were calculated by propagating the fit uncertainties. Otherwise the errors were calculated by finding the standard deviation of multiple measurements. Devices labeled with a “*” were fit without constraining the line of best fit to be normalized and have the proper offset. The average T_{2,CPMG} column denotes the time averaged dynamical decoupling decoherence time at an optimal gate number.

Switching from niobium to tantalum alone increased the average T₁ for a Purcell-filtered qubit to 150 μs (Device 2a), already a significant improvement over the best published 2D transmon lifetime. To study the impact of heating the substrate during deposition, a device was made from niobium sputtered at 500° C. (Device Nb2). This resulted in a T₁ of 79±1 μs, an improvement over previous niobium devices, but not comparable to tantalum-based devices. This indicates that thermal cleaning of the substrate may play a role in enhancing T₁, but does not completely explain our improved coherence.

Iterative improvements to processing, including the use of wet etching to pattern the tantalum layer and the introduction of additional cleaning steps, further improved qubit lifetimes to the levels reported in FIG. 2B (Devices 11-18). Specifically, a piranha cleaning process was introduced to clean particulates and contaminants from the substrate surface. Removal of particulates can be verified using atomic force microscopy (AFM), and the signal due to adventitious carbon measured by x-ray photoelectron spectroscopy (XPS) is attenuated after cleaning. In addition, the introduction of an optimized wet etch process to pattern the tantalum resulted in improved edge morphology compared with reactive ion etching. Of the ten devices measured prior to the optimized wet etch, none had a T₁ in excess of 200 μs; of the eight patterned with the optimized wet etch and fabricated with our substrate cleaning procedure, six had a T₁ greater than 200 μs. The metal residue and poor edge morphology may limit qubit lifetimes.

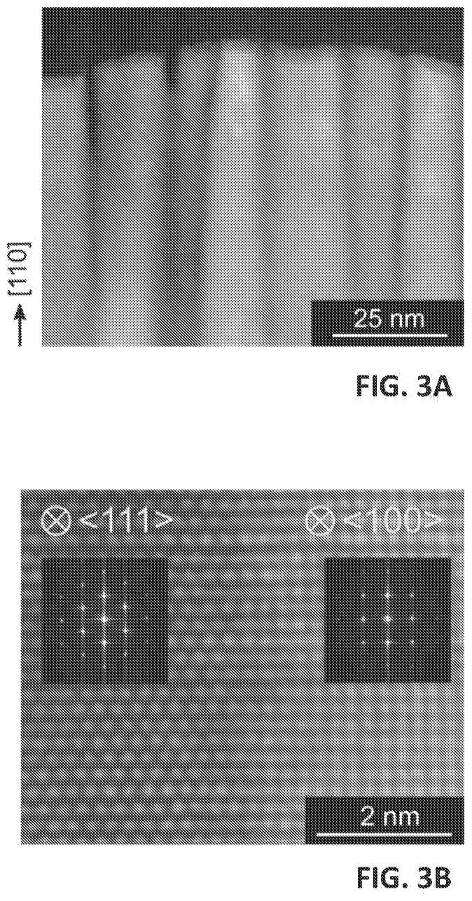

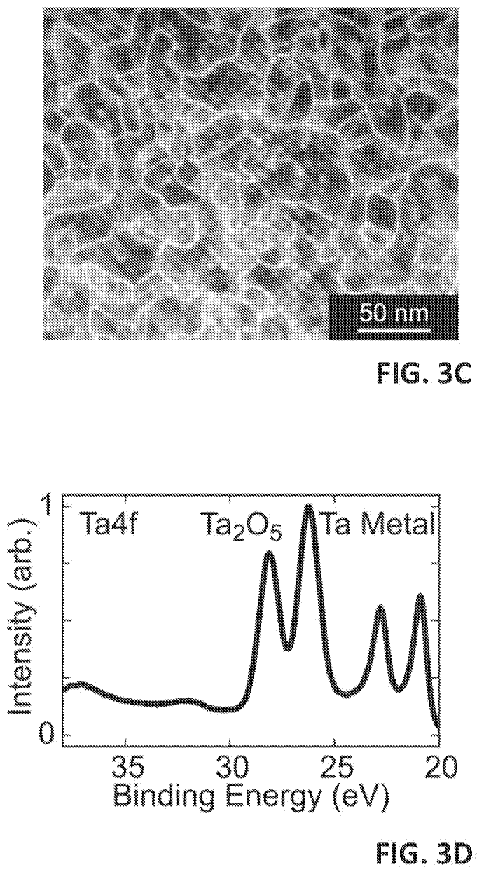

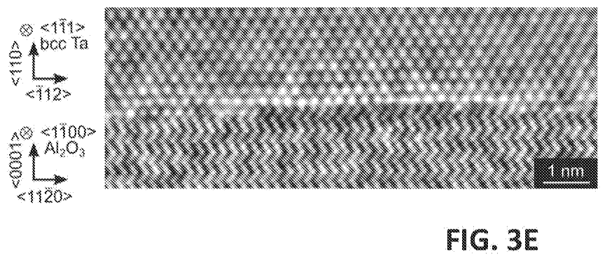

Because the crystal structure of thin tantalum films sensitively depends on deposition parameters, detailed characterization of the deposited tantalum films are presented. FIGS. 3A-D show microscopy and spectroscopy of tantalum films. FIG. 3A shows STEM image of the tantalum film, showing single-crystal columns with the growth direction oriented along the [110] axis. FIG. 3B shows atomic resolution STEM image of an interface between two columns, viewed from <11̅1> and <001> zone axes respectively. Fourier transforms (insets) of the image show that the columns are oriented with the image plane perpendicular to the <111> or <100> directions. FIG. 3C shows a STEM image of a horizontal device cross section, showing grain boundaries. Image contrast at grain boundaries results from diffraction contrast caused by interfacial defects. FIG. 3D shows an XPS spectrum of a device, exhibiting peaks from tantalum metal and Ta₂O₅. FIG. 3E shows High-resolution STEM with integrated differential phase contrast imaging of the interface between the sapphire and tantalum showing epitaxial growth.

Microscopy and spectroscopy of the deposited tantalum confirms the BCC structure of the film and reveals that it is highly oriented. Scanning transmission electron microscopy (STEM) of a film cross section reveals a columnar structure, with the growth direction oriented along the [110] axis (FIG. 3A). It is confirmed that the films are oriented over a larger area using x-ray diffraction (XRD) measurements. Atomic-resolution STEM reveals that the individual columnar grains are single-crystal, with the front growth face perpendicular to either the <100> or <111> directions (FIG. 3B). The different orientations result from the underlying three-fold symmetry of the sapphire c-plane surface. A top-down plane view cross-sectional STEM shows that the grains range in size from around 5 to 50 nm (FIG. 3C). Elemental analysis using energy dispersive spectroscopy (EDS) shows that there is no oxide growth between the grains, and the image contrast observed in FIG. 3C arises from diffraction contrast due to interfacial defects at grain boundaries.

Properties of the native tantalum oxide were studied in the example devices using photoelectron spectroscopy to probe large areas and electron microscopy to directly image the oxide layer in a small cross section. XPS shows a set of four peaks with binding energy between 20 and 30 eV, assigned to the Ta 4f core ionization. The two lower binding energy peaks are spin-orbit split peaks associated with Ta metal, while the two higher binding energy peaks are consistent with Ta₂O₅ (FIG. 3D). The small peaks at higher binding energies likely correspond to 5p photoelectron emission from the metal and oxide. The relative intensity of the Ta and Ta₂O₅ peaks indicates that the oxide is approximately 2 nm thick, given an inelastic mean free path of electrons in tantalum of 2 nm at 1480 eV. This is consistent with measurements of the oxide thickness using angle-resolved XPS. High-resolution STEM also verifies that there is a 2-3 nm thick amorphous layer at the surface of the film. It was observed that the apparent oxide thickness and composition are similar across different depositions and are robust to processing steps, including lithography and piranha etching.

The interface between the sapphire surface and the sputtered tantalum were directly imaged using integrated differential phase contrast imaging (iDPC) under STEM (FIG. 3E). The interface shows an atomically sharp boundary with clear evidence of epitaxial growth, in which the tantalum atomic layer is directly grown on top of the oxygen atomic layer in the sapphire. The interfacial dislocations likely result from the 12.6% lattice mismatch between the [1̅12] axis of tantalum and the [112̅0] axis of sapphire, as well as atomic layer steps in the sapphire that are evident in the STEM image.

It was demonstrated that tantalum 2D transmon qubits using the techniques described herein exhibit longer T₁ and T₂ than the previous state of the art with remarkable consistency. Building on these relatively simple materials improvements, there are several areas of future exploration. First, T_{2,Echo} is shorter than T₁ for all tantalum devices measured. Combining the example devices with recent improvements in shielding and filtering will allow exploration of the microscopic mechanisms for decoherence. Additionally, ongoing work includes more systematic characterization of the effects of specific material properties on microwave losses. In particular, the tantalum grain size, oxide thickness, and heteroepitaxial growth interface quality may impact T₁ and T₂. Furthermore, it has been well-established that multi-qubit devices suffer from significant variation between qubits, as well as variation over time in the same qubit. An interesting question is how particular material choices quantitatively affect these variations, and whether judicious material choice can narrow the distribution of device properties. Finally, although observed a large improvement is observed over niobium-based devices, it should be noted that several groups employ all-aluminum qubits. Contamination and interfaces may play a role in the coherence of all-aluminum qubits, as well as the possibility of fabricating all-tantalum qubits.

More broadly, the results demonstrate that systematic materials improvements are a powerful approach for rapid progress in improving quantum devices. These techniques can also be employed to improve spin coherence of shallow nitrogen vacancy centers in diamond. Many other quantum platforms may be limited by noise and loss at surfaces and interfaces, including trapped ions, shallow donors, and semiconductor quantum dots. The general approach described herein may allow for directed, rational improvements in these broad classes of systems as well.

1.1 Fabrication Procedure

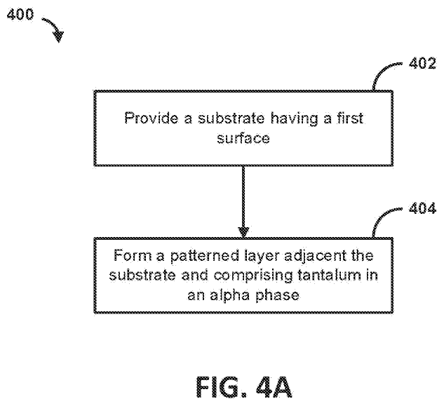

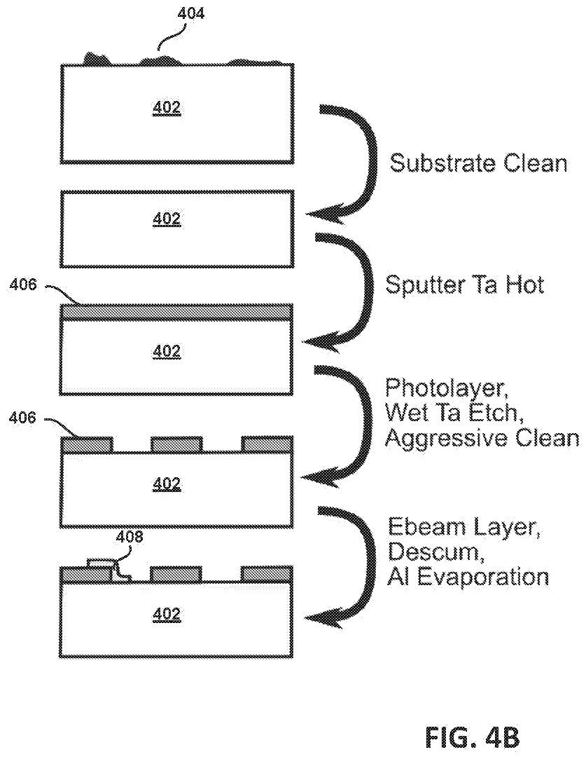

FIG. 4A shows an example method 40 for fabricating a device, such as a device for forming a superconducting qubit. The device may comprise any device disclosed herein.

At step 402, a substrate may be provided. The substrate may comprise sapphire, silicon, or a combination thereof. The substrate may have a first surface. The first surface of the substrate may be treated by at least one of etching with a heated sulfuric acid etch, cleaning the first surface with a piranha cleaning solution, cleaning by oxygen plasma, or annealing the first surface at an annealing temperature. The annealing temperature may be one or more of: in a range of 1300° C. to 1500° C., or high enough to cause the sapphire surface to form atomic steps, as measured by atomic force microscopy. The substrate may be polished. The polished substrate may be etched with a heated sulfuric acid etch.

At step 404, a patterned layer may be formed. The patterned layer may be formed adjacent the substrate. The patterned layer may comprise tantalum in an alpha phase. The patterned layer may at least a part of a structure for storing a quantum state. The structure may comprise one or more of a qubit, a transmon qubit, a X mon qubit, a three-dimensional transmon qubit, a fluxionium qubit, or a zero-pi qubit. The structure may be free of niobium. A relaxation time of the quantum state may comprise one or more of at least 150 μs, at least 200 μs, or at least 300 μs. A relaxation time of the quantum state may be in a range of one or more of 150 μs to 317 μs or 200 μs to 317 μs.

Forming the patterned layer may comprise forming a layer of tantalum in the alpha phase and patterning the layer of tantalum using an etching process. The etching process may comprises a wet etch process. Forming the patterned layer may comprise performing a sputtering-deposition of tantalum at a predetermined deposition temperature onto the first surface after applying an annealing process to the first surface. In situ heating may be provided during a sputtering-deposition of tantalum to form a film of tantalum on the alpha phase.

Forming the patterned layer may comprise forming at least a portion of a circuit component comprising the tantalum in the alpha phase. The circuit component may comprise one or more of a capacitor, an inductor, or a Josephson junction. Forming the patterned layer may comprise forming one or more electrical circuit components configured to cause the quantum state to be stored based on enabling non-harmonic energy levels for forming qubit states.

The method 400 may further comprise treating one or more of the substrate and a tantalum film used to form the patterned layer by at least one of: cleaning an exposed surface of the tantalum film with a piranha cleaning solution, or treating the exposed surface of the tantalum film with an oxygen plasma descum.

One or more additional layers may be formed. The one or more additional layers may form one or more electric components. The patterned layer and the one or more additional layers may form an electrical circuit. The electrical circuit may be configured to form energy levels for storing the quantum state. The one or more additional layers may comprise a Josephson junction.

FIG. 4B shows an example qubit fabrication process. The sapphire substrate 402 is initially contaminated with carbon 404 which may be reduced through substrate cleaning. Tantalum 406 may be deposited and subsequently patterned with a wet etch. Finally, the Josephson junctions 408 may be lithographically defined and deposited. 2D transmon qubits may be fabricated on a sapphire substrate, such as a c-plane sapphire substrates (Crystec GmbH). The sapphire substrate may be, for example, 0.53 mm thick and double-side polished. Prior to deposition, the wafer may be dipped in a piranha solution then cleaned with an oxygen plasma (Technics PE-IIA System) immediately before loading into the sputterer.

Tantalum may be deposited on the sapphire substrate at high temperature (e.g., approximately 500° C., Star Cryoelectronics). Before photolithography, the tantalum-coated substrates may be piranha-cleaned (e.g., placed in a 2:1 mixture of H₂SO₄ and H₂O₂ for 20 minutes). After the piranha cleaning, the tantalum-coated substrate may be heated on a hotplate for 5 minutes at 140° C. before AZ 1518 resist is spun (Merck KGaA). The resist may be patterned using a direct-write process (2 mm write head on a Heidelberg DWL 66+ Laser Writer). After developing (e.g., 85 sec in AZ 300MIF developer from Merck KGaA), the resist may be hard-baked for 2 min at 115° C. Unwanted residual resist may be removed using a gentle oxygen descum (2 min in 30 mTorr O₂ with 20 W/200 W RF/ICP coil power in a Plasma-Therm Apex SLR). Next, the tantalum may be etched in a 1:1:1 ratio of HF:HNO₃:H₂O (e.g., Tantalum Etchant 111 from Transene Company, Inc.) for 21 sec. After stripping resist, the device may be solvent-cleaned by sonicating in toluene, acetone, methanol, and isopropyl alcohol (“TAMI-cleaned) then piranha-cleaned. The patterned tantalum may be prepared for electron beam lithography to define Josephson junctions (MMA 8.5 MAA, 950 PMMA, with a 40 nm layer of evaporated aluminum to dissipate charge), then the chips may be diced into 7×7 mm squares.

Liftoff patterns for Manhattan junctions with overlap areas of approximately 0.03 μm² may be then exposed (e.g., Elionix ELS-F125). The anticharge layer may be removed through a 4 min bath in MF 319 (e.g., Rohm and Haas Electronic Materials LLC) followed by a 50 sec bath in a 1:3 mixture of methyl isobutyl ketone to isopropyl alcohol. Next, the device may be loaded into an electron beam evaporator (e.g., Plassys MEB 5505) and ion-milled (e.g., 400 V, 30 sec along each trench of the junction). Immediately after, aluminum (e.g., 15 nm) may deposited (e.g., at 0.4 nm/sec at a pressure of approximately 10′ mBar). After depositing aluminum, a 15 min, 200 mBar oxidation period may be performed. Finally, a second layer of aluminum (e.g., 54 nm) may be deposited to form the second layer of the junction. The same evaporation parameters (e.g., for Device 18a, 15 nm and 19 nm of aluminum are deposited, respectively) may be used as before. The resist may be removed. For example, the resist may be removed by soaking the sample in Remover PG (Kayaku Advanced Materials, Inc.) for approximately 3 hours at 80° C., briefly sonicating in hot Remover PG, then swirling in isopropyl alcohol.

1.1.1 Tantalum Etch

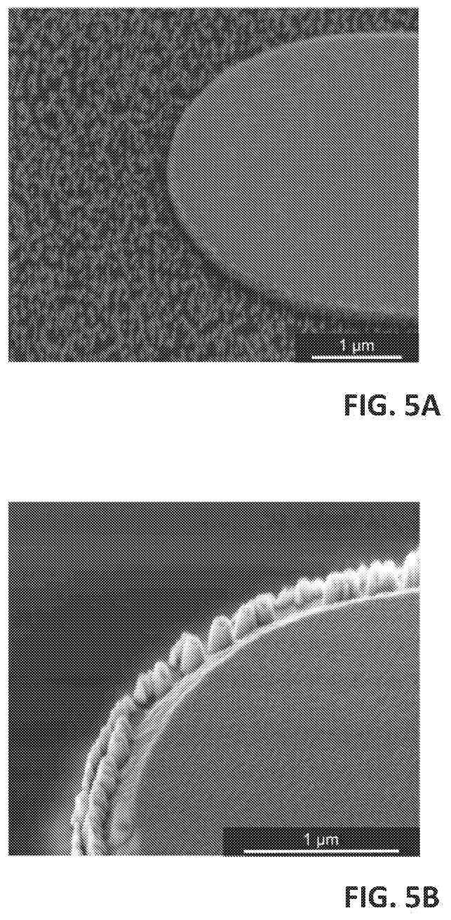

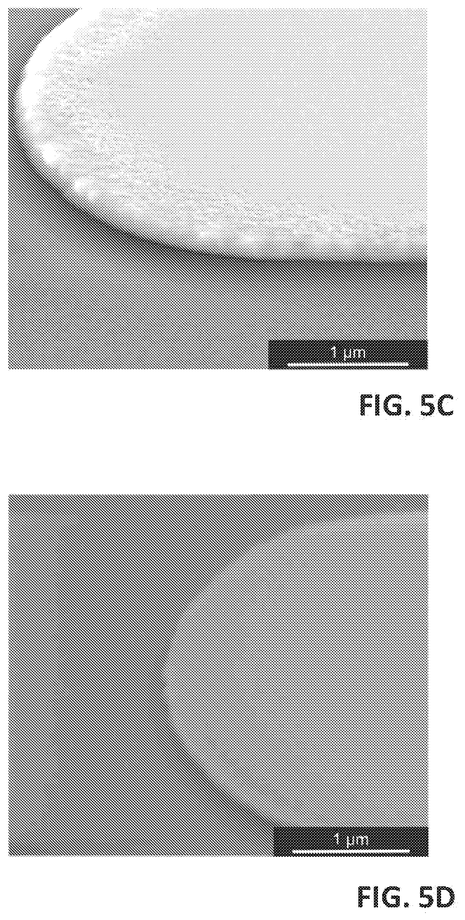

FIGS. 5A-D show scanning electron microscopy images of tantalum etch development. In all panels tantalum capacitor pads on a sapphire substrate protrude from the right side of the image. FIGS. 5A-B show examples of surface roughening after a 8:3:2 CHF₃:SF₆:Ar dry etch with a 5-7 mTorr pressure and RF/ICP power 30 W/30 W (FIG. 5A) and 100 W/100 W (FIG. 5B). The rough features near the sidewalls in FIG. 5B survived both a piranha etch and an oxygen plasma etch. FIG. 5C shows initial wet etch results showed roughening of the tantalum near the edge of the pad, which was circumvented FIG. 5D by employing a thicker photoresist.

Initially, tantalum was etched using a reactive-ion etch (e.g., 8:3:2 CHF₃:SF₆:Ar chemistry at 50 mTorr, RF/ICP power of 100 W/100 W). However, scanning electron microscopy (SEM) images showed rough edges as well as small pillars and boulders near the sidewalls, likely due to micromasking (FIG. 5A, B). The anomalous objects in FIG. 5B remained after the device was cleaned in piranha solution and treated in an oxygen plasma. In order to avoid these fabrication problems, a wet etch was performed (e.g., a wet etch composed of 1:1:1 HF:HNO₃:H₂O). It was found that several resists delaminated before the tantalum was etched through, leaving the sidewalls and nearby tantalum visibly rough in SEM (FIG. 5C). This problem was circumvented by using thick AZ 1518 resist (e.g., approximately 2 μm tall) which left cleaner sidewalls (FIG. 5D). Comparing Devices 4-10 with Devices 11-18 in Table S1, it should be noted the optimized wet etch likely improved T₁.

1.1.2 Sapphire Preparation

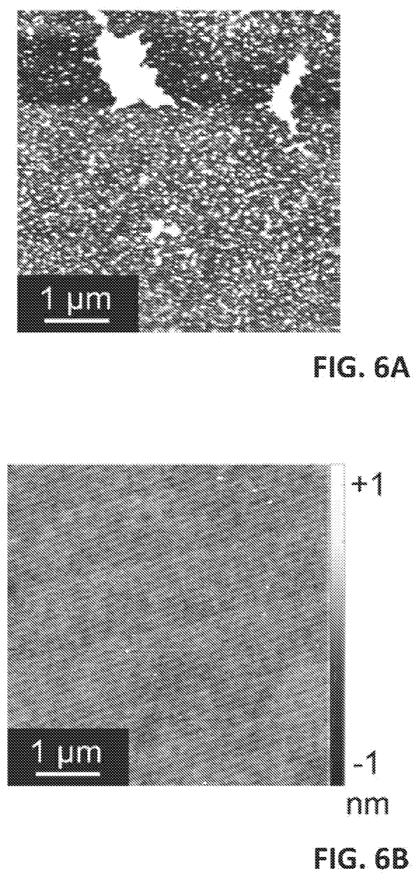

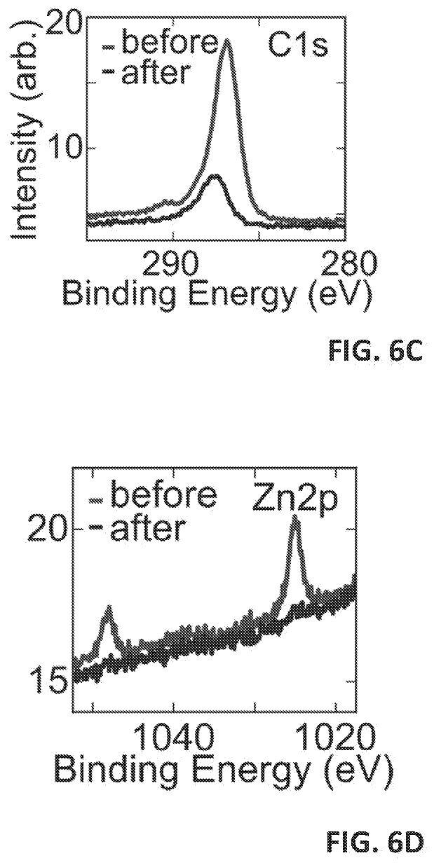

Aggressive cleans and etches may be used to remove the contaminants on samples after dicing, stripping resist, and sonicating in solvents. FIGS. 6A-D show characterization of a sapphire surface. AFM images are shown of sapphire after dicing, strip-ping resist, and solvent cleaning (FIG. 6A) and after subsequent piranha cleaning and etching (FIG. 6B), showing the removal of particulates from the surface. XPS of sapphire identifies carbon (FIG. 6C) and zinc (FIG. 6D) contaminants on the sapphire surface. After piranha cleaning and etching, carbon is reduced by around a factor of five, and zinc is no longer detected. “Before” corresponds to the surface after dicing and solvent cleaning but before acid procedures, and “after” is following acid cleaning steps.

The AFM images reveal an abundance of particulates on the surface (FIG. 6A), which are removed by cleaning in piranha solution (FIG. 6B). Additionally, the carbon signal in XPS is attenuated by a factor of 5 after piranha cleaning, illustrating a reduction in carbon contamination (FIG. 6C). XPS also reveals zinc contamination that persists through a piranha clean, but can be removed by etching the sapphire substrate in heated sulfuric acid (FIG. 6D).

The sapphire surface was prepared using this sulfuric acid etch in Devices 9-14 and 17. In these devices, the wafers are covered with a protective layer of photoresist and then diced into 1 inch squares. After removing resist, the squares are TAMI cleaned and piranha cleaned. Next, the sapphire is placed into a quartz beaker filled with H₂SO₄ sitting on a room temperature hotplate. The hotplate is set to 150° C. for 20 minutes, followed by a 10 minute cooldown period before removing the device. It is estimated that less than 1 nm of the surface is removed. To avoid residue from the etch, the device may be piranha cleaned again. The device may then packaged, shipped, and loaded into a sputterer without further cleaning.

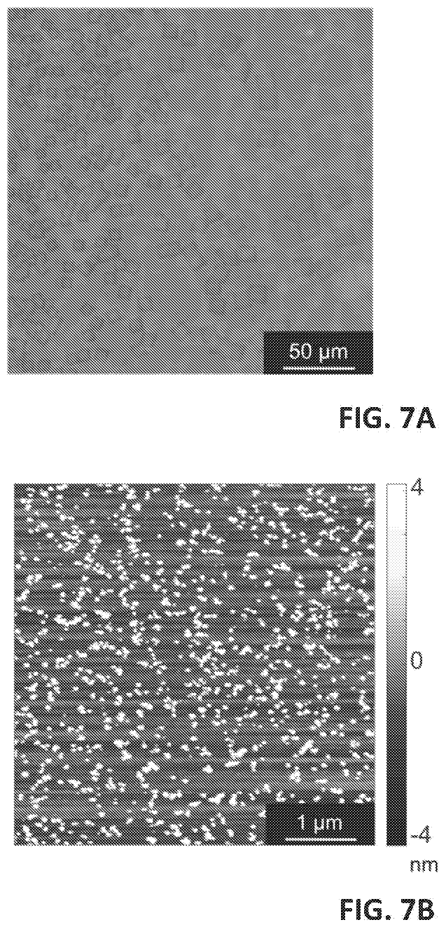

FIGS. 7A-B show sapphire processing pitfalls. FIG. 7A shows an optical microscope image of crystals on sapphire after etching in refluxing sulfuric acid for 30 min. FIG. 7B shows an AFM image of sapphire surface showing particulate contaminants after etching and piranha cleaning in borosilicate glassware. Calibrating the time and temperature of the sapphire etch is important to maintaining a smooth surface morphology while still removing zinc. In particular, polycrystalline aluminum sulfates form on the sapphire surface after heating in sulfuric acid for too long and at too high of a temperature (FIG. 7A). The sapphire etch recipe may be developed by (1) looking for crystal formation in an optical microscope, (2) ensuring that zinc was removed in XPS, (3) checking that we preserved smooth surface morphology in AFM, or a combination thereof. It is noted that the zinc appeared to be inhomogeneously distributed on the surface and so multiple spots were routinely checked in XPS. After adjusting the time and temperature to the optimum procedure outlined above, no crystal formation was detected.

Additionally, surface contamination was observed with AFM from etching sapphire in borosilicate glassware. An example of surface particulate contamination is shown in FIG. 7B. Switching to a quartz beaker solved this issue.

It is noted that Devices 16 and 18 were not processed using the sapphire etch, and they exhibited T₁ over 0.2 ms. The sapphire material properties on device performance may be further improved by fabricating devices on higher-purity sapphire, removing polishing-induced strain by etching a more appreciable amount of the substrate, annealing to form an atomically smooth surface, or a combination thereof

1.2 Device Packaging

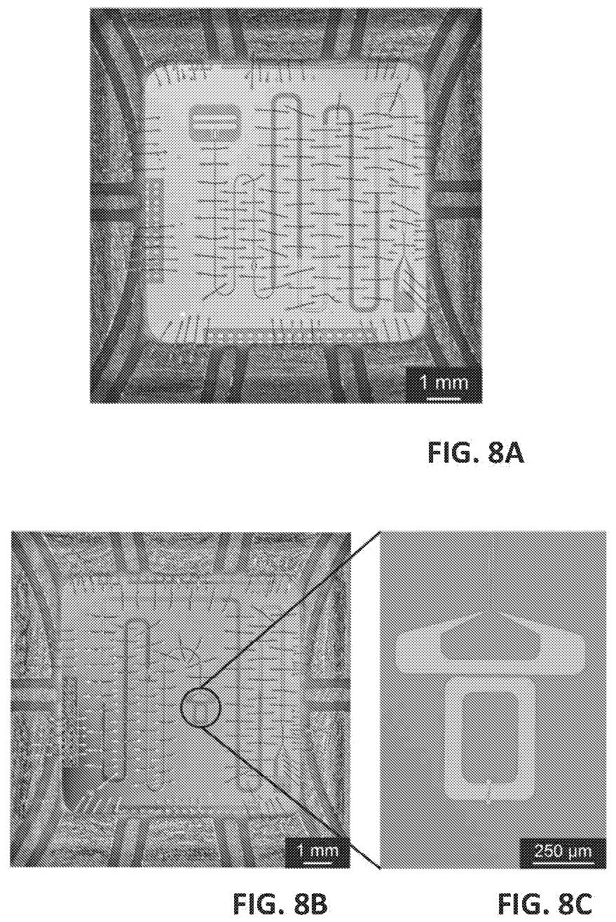

FIGS. 8A-C shows example device geometry overview. FIG. 8A shows an image of an example double pad transmon qubit mounted to a printed circuit board. FIG. 8B shows an image of an example Xmon qubit mounted to a printed circuit board. In each case, the chip is pressed beneath an opening in a PCB that has copper traces, here visible around the outside of the images. The excitation and measurement pulses first enter the curving Purcell filter, go through a capacitive coupler to the resonator, then to the qubit. It should be noted in FIG. 8B that the qubit is shown in the center of the chip. FIG. 8C shows close-up, false-colored SEM image of the Xmon qubit and coupler.

The completed devices may be mounted to a printed circuit board (PCB). The edge of the tantalum ground plane may be firmly pressed against the PCB's copper backside (e.g., sandwiched between the PCB and a piece of aluminum-coated oxygen-free copper). The device may be wirebonded (FIG. 8A, B). An aluminum-coated oxygen-free copper lid may be placed above the qubit (e.g., Table 1 column “Enclosure Lid Removed”), forming a superconducting enclosure partially surrounding the qubit. The device may be mounted in a dilution refrigerator with a base temperature of approximately 9-20 mK. The qubit and PCB may be wrapped in several layers of aluminized my-lar sheeting and suspended by an oxygen-free copper rod in the middle of an aluminum cylinder coated with microwave-attenuating epoxy or sheeting (Laird Performance Materials Eccosorb Cr or Loctite Stycast). This cylinder may be enclosed in a mu-metal can to reduce the penetration of ambient magnetic fields into the aluminum during the superconducting transition. Both cans may be then wrapped in several layers of mylar sheeting.

It should be noted note that all of the example double-pad transmons presented in this text are positioned approximately 2 mm away from the copper traces on the PCB (FIG. 8A), which could result in loss due to parasitic coupling of the qubit to the resistive traces. In order to reduce this possible source of loss, devices fabricated with the Xmon geometry may be moved close to the center of the sapphire chip (FIG. 8B).

1.3 Measurement Setup

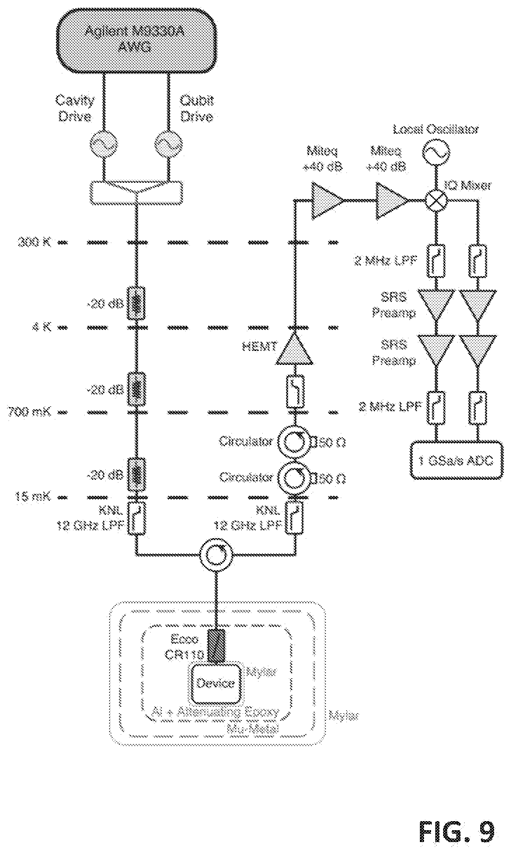

Each transmon may be capacitively coupled to a microwave resonator, allowing the state of the qubit to be measured dispersively. The transmon frequencies range from 3.1-5.5 GHz while the resonators range in frequency from 6.8-7.3 GHz. An overview of the setup used to measure a majority of the devices is given in FIG. 9, which shows a schematic of the measurement electronics and device shielding. An Agilent E8267D vector signal generator, Holzworth HS9004A RF synthesizer, and Keysight M9330A Arbitrary Waveform Generator may be used to synthesize the excitation and measurement pulses. The input signals may be combined into a single line and then attenuated on each plate of the dilution refrigerator. An additional filter made of Eccosorb CR110 epoxy may be placed in the aluminum can to attenuate high-frequency radiation. Measured in reflection, the output signal may be sent through a circulator (Raditek RADC-4-8-cryo-0.01-4K-S23-1WR-ss-Cu-b), two isolators (Quinstar QCI-075900XM00), superconducting wires, and then a high-electron-mobility transistor amplifier (Low Noise Factory LNF-LNC4 8C) at 4 K. After the signal is amplified at room temperature (through two MITEQ AFS4-00101200 18-10P-4 amplifiers), it may be measured in a homodyne setup by first mixing it with a local oscillator (Holzworth HS9004A), further amplifying (Stanford Research Systems SR445a), and then digitizing (Acqiris U1084A).

1.4 Other Device Designs and Fabrication Processes

As shown above, Table 1 summarizes different iterations of the fabrication procedure. Initially a tantalum transmon was made using our standard niobium processing techniques (reactive ion etching, no acid cleaning). This material switch alone improved the coherence time by more than a factor of four compared to the control sample (see e.g., Table 1, Devices 1a and Nb1). We then began to iterate our packaging and fabrication techniques to explore the new dominant loss mechanisms.

First losses unrelated to the qubit materials and interfaces may be minimized. The density of photonic states at the qubit frequency may be reduced by means of a Purcell filter (Device 2a and all subsequent devices). Aluminum shielding may be placed on a majority of the copper enclosure immediately surrounding the device to reduce dissipative currents induced by the qubit in the surrounding metal. A mylar sheet wrapped around the PCB may be used as an extra layer of shielding. Both added layers give additional protection from high-energy radiation (e.g., used in Device 2b and all subsequent devices).

Next material contaminants were reduced. XPS measurements revealed significant carbon residue that persisted after solvent-based cleaning. Accordingly, carbon contamination may be reduced, such as by adding a piranha clean before spinning e-beam resist (e.g., Device 4a and all subsequent devices). As mentioned above, the sapphire substrate may be cleaned prior to tantalum deposition. For Devices 1-8, 15-16, and 18 as well as Nb1, Nb2, and 3D1, the sapphire substrate may be dipped in a piranha solution and cleaned with an oxygen plasma (Technics PE-IIA System) immediately before loading into the sputterer. For the rest of the sapphire devices, the substrate may be cleaned with the sapphire etch described above (e.g., in Section 1.1), packaged and shipped the samples, then deposited the tantalum.

The tantalum etch was analyzed, described in more detail above (e.g., Section 1.1). Devices 1-6, Nb 1-2, Si1, and 3D1 were all fabricated with reactive ion etching. Devices 7-10 and 3D2 were made using initial versions of the wet etch (using different resists, etch times, and acid concentrations), where the etch clearly roughened the sidewalls (FIG. 5C). Devices 11-18 were made using the optimized wet etch.

1.4.1 2D Transmons on Sapphire

Two different geometries of transmons were measured: devices with double-pad capacitors (e.g., where neither pad has a direct ground connection, as shown in FIG. 1A), and Xmon-style devices, where the ground plane serves as one side of the transmon's capacitor.

1.4.2 2D Transmon on Silicon

A 2D, double-pad, tantalum transmon was fabricated on silicon (Device Si1) with a similar design to that used for the devices on sapphire. The primary elements that changed during the fabrication process were: (i) a different plasma etch time to avoid overetching into the silicon, (ii) no aluminum layer was deposited on top of the e-beam resist prior to e-beam lithography, and (iii) the e-beam intensity was adjusted during the lithography step. It was found that reactive-ion etching severely roughened the silicon surface (17 nm RMS surface roughness, measured with a Keyence Optical Profilometer).

1.4.3 3D Transmons

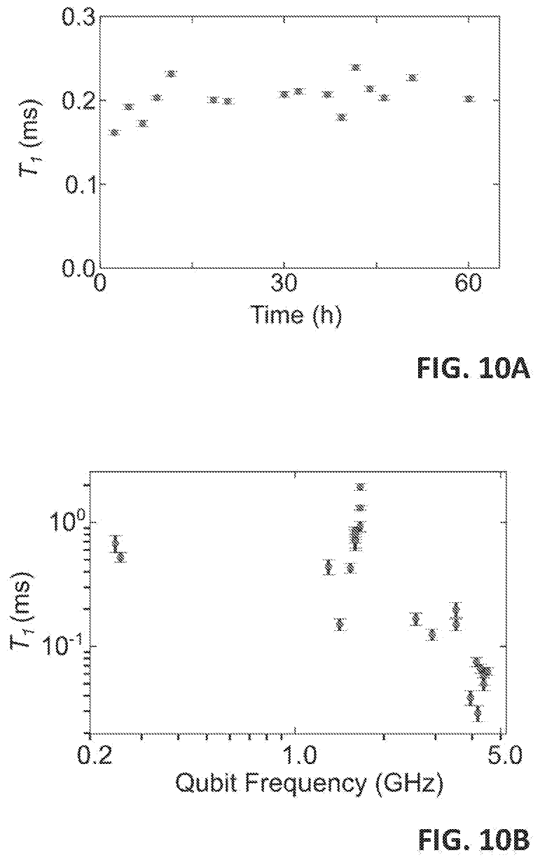

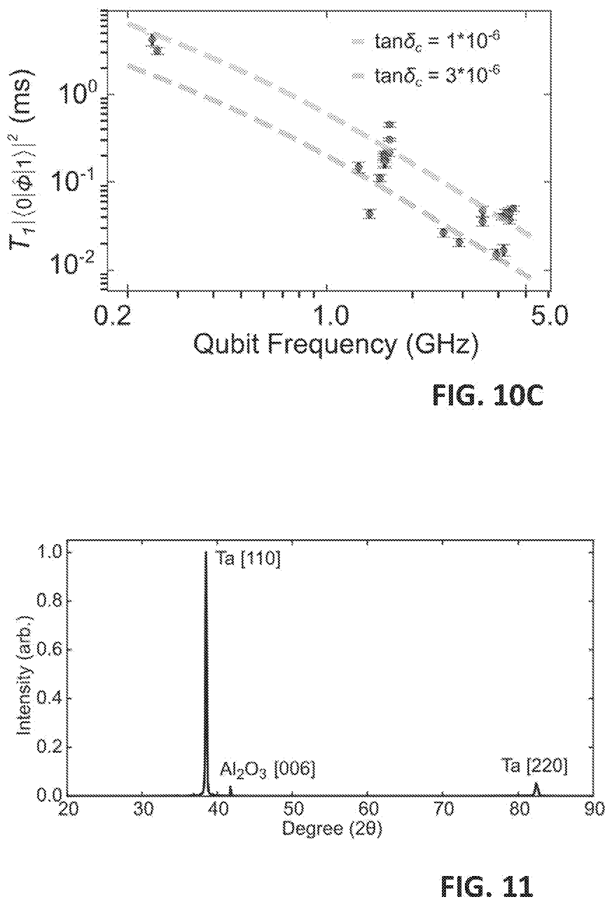

FIGS. 10A-C shows Tantalum 3D and fluxonium devices. FIG. 10A shows measurement of T₁ over time for Device 3D1. FIG. 10B shows Fluxonium T₁ as a function of frequency which can be fit to determine the dielectric loss tangent FIG. 10C when combined with the phase matrix element between logical qubit states, <0|\hat{Ø}|1>. 3D transmons were mounted in an 8.0 GHz aluminum rectangular cavity with a 250 kHz linewidth. Double-pad transmons were fabricated with the same process described above on approximately 2.5×7.5 mm sapphire chips. After the aluminum cavity was etched (4 hours in Aluminum Etchant Type A from Transene Company, Inc.) to remove any contaminants and machining cracks, the device was mounted in the center of the resonator and indium foil was compressed between the two aluminum halves to seal the seam. The same shielding was used for the 2D and 3D devices other than the aluminum cylinder directly inside the mu-metal shielding, which was too small to fit around the 3D cavity.

For Device 3D1, the measured cavity resonances were significantly different than expected. This is attributed to a thin layer of aluminum that was deposited on the side of the sapphire chip during the double-angle Josephson junction evaporation. On later devices, the metal was cleaned from the side of the chip, and the measured resonance was as expected. A mean T₁ of 0.20±0.02 ms was measured for Device 3D1 (FIG. 10A). 3D transmon devices may be optimized by focusing on measurement of 3D devices that were fabricated with wet etch processing.

1.5 Tantalum Fluxonium

A light fluxonium qubit was made using tantalum capacitor pads and aluminum junctions. The example qubit had a Josephson energy of 0.92 GHz, a capacitive energy of 3.6 GHz, and an inductive energy of 0.53 GHz. A plasmon T₁ of 0.063:L 0.004 ms and a maximum fluxon T₁ of 1.9±0.2 ms was measured, although time fluctuations in the fluxon T₁ on the order of a millisecond were observed. The resonant frequency of a fluxonium qubit is flux-tunable. By fitting T₁ as a function of resonant frequency, a dielectric loss tangent of 1-3·10⁻⁶ (FIG. 10C, D) was deduced.

1.6 Additional Materials Characterization

1.6.1 X-Ray Diffraction

FIG. 11 shows x-ray diffraction spectrum of a sputtered tantalum film on sapphire. XRD spectrum of sputtered tantalum on sapphire shows clear peaks corresponding to α-tantalum and sapphire. A few unassigned small peaks are also visible which could be caused by contamination, instrumental artifacts, or impurities in the films. XRD was used to study the crystal structure of the films over a much larger area than is feasible with STEM images (FIG. 11). An acquired spectrum of a film exhibits a strong peak corresponding to α-tantalum [110], corroborating STEM images that suggest that the example films grew uniformly along that direction (FIG. 3A). Additionally, peaks corresponding to sapphire [006] and α-tantalum [220] were observed. There was no detection of a β-tantalum [002] peak at 33.7° (2θ). This provides further evidence along with the T_{c} and STEM measurements that the tantalum films are uniformly in the a phase. It should be noted that there are a few unassigned small peaks which could result from contamination, instrumental artifacts, or impurities or defects in the tantalum films.

1.6.2 Grain Boundaries

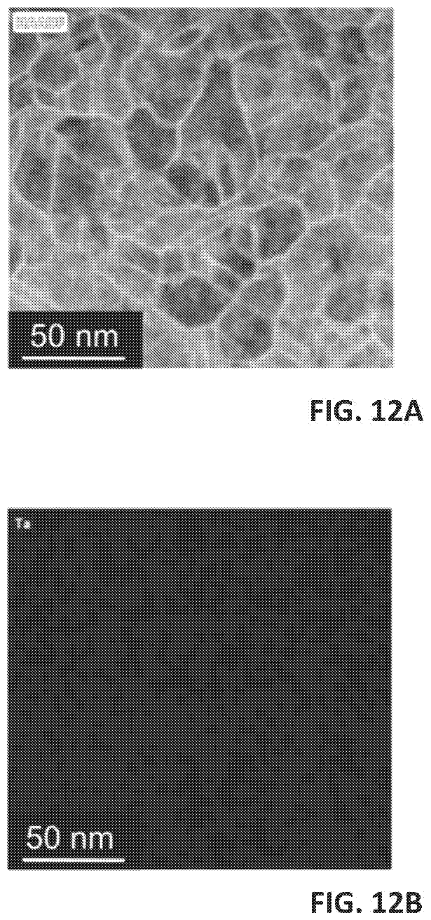

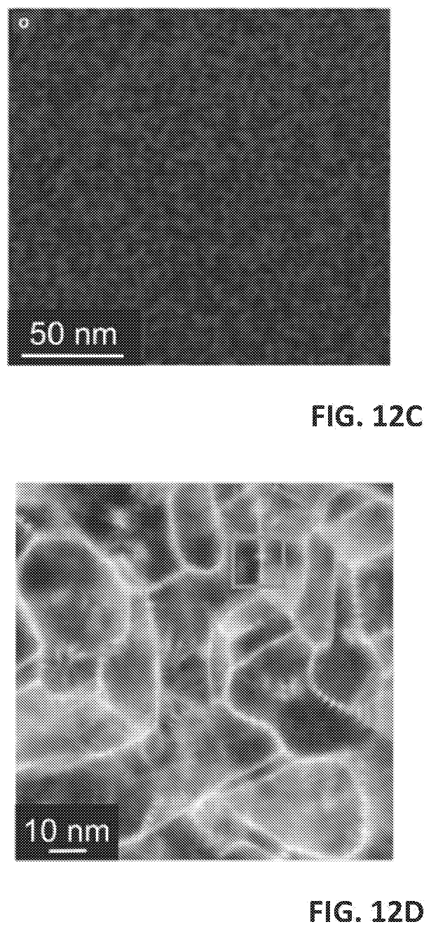

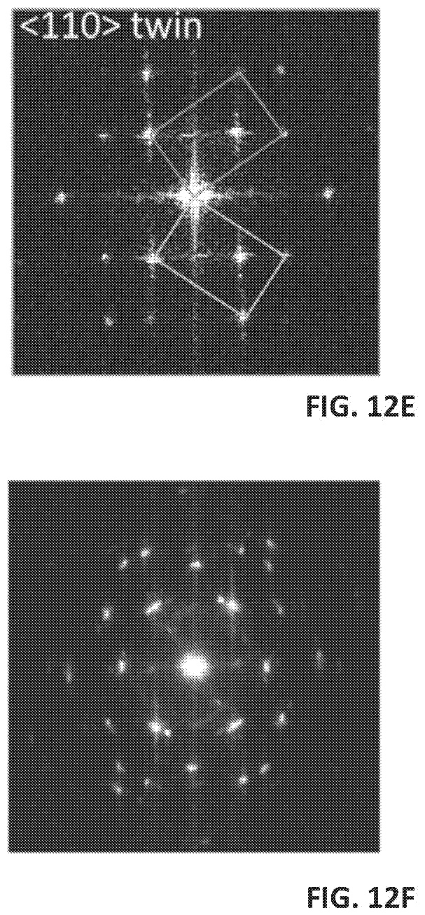

FIGS. 12A-F show grain boundary characterization. FIG. 12A shows a plane-view STEM image showing grain boundaries. FIGS. 12B-C show EDS maps of the same region shown in FIG. 12A, displaying a uniform distribution of tantalum (FIG. 12B) and oxygen (FIG. 12C). FIG. 12D shows atomic resolution STEM image of the boundaries. FIG. 12E shows a Fourier transform of the STEM image at a grain boundary indicated by the box region of FIG. 12D, showing a pattern consistent with twinning. FIG. 12F shows a Fourier transform of the entire image in FIG. 12D shows the rotational symmetries of the grains.

The grain boundaries visible in a plane-view image were analyzed (FIG. 12A) by using energy dispersive x-ray spectroscopy (EDS) to perform spatially-resolved elemental analysis. A uniform distribution of tantalum (FIG. 12B) and oxygen (FIG. 12C) was found over the region, and no oxygen enrichment at the grain boundaries. This suggests that the example films do not grow oxide between the grains, and that the image contrast observed in FIG. 12A arises instead from diffraction contrast caused by interfacial defects.

A high-resolution STEM image of a grain boundary elucidates the crystal structure at the boundaries (FIG. 12D). Taking a diffraction pattern of a grain boundary region indicated by a green square in FIG. 12D gives a pattern consistent with twinning (FIG. 12E). A diffraction pattern of the whole region in FIG. 12D illustrates the rotational symmetries of the grains (FIG. 12F).

1.6.3 Tantalum Oxide

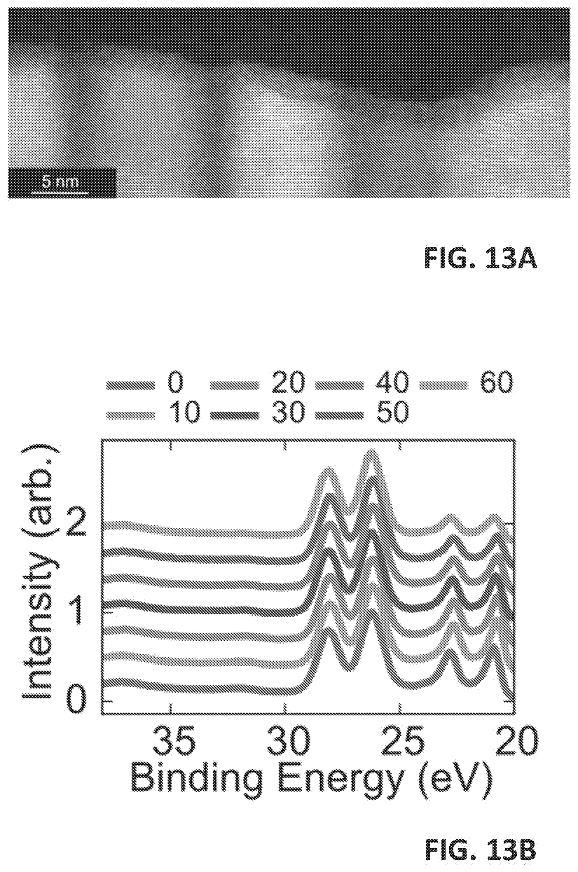

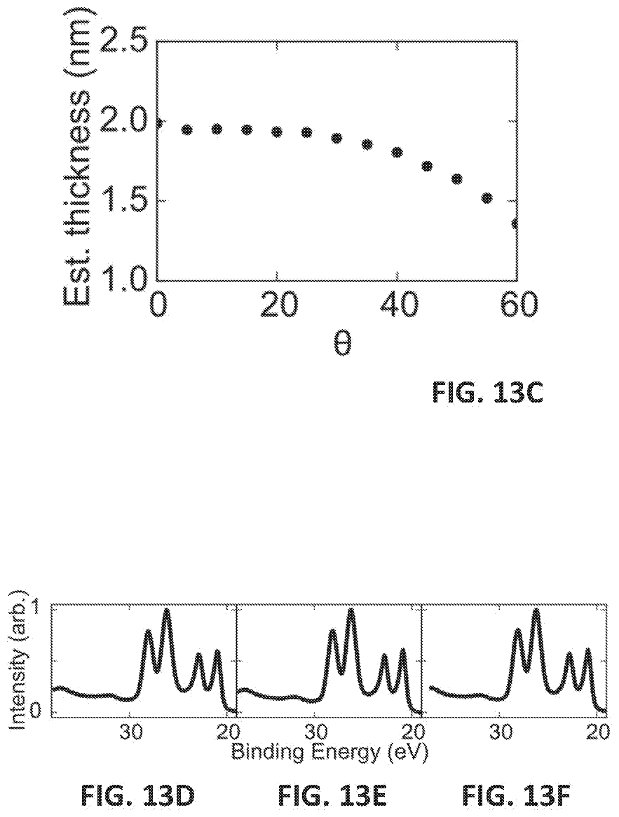

FIGS. 13A-F show oxide characterization. FIG. 13A shows an atomic resolution STEM image showing an amorphous oxide layer about 2-3 nm thick on the tantalum surface. FIG. 13B shows an angle-resolved XPS measurements of Ta4f region of a fabricated device, offset vertically for clarity. Colors indicate the angle in degrees between sample and detector. FIG. 13C shows estimated oxide thickness as a function of angle between sample and detector. FIGS. 13D-F show Ta4f normal incidence XPS data of three completed devices showing nearly identical spectra. The devices were from different tantalum depositions and underwent different fabrication steps. In addition to other variations in fabrication, the device in FIG. 13D was only solvent cleaned while the devices surveyed in FIG. 13E and FIG. 13F were piranha cleaned.

An atomic-resolution STEM image of a 50 nm region of the tantalum surface reveals an amorphous oxide that is 2-3 nm thick (FIG. 13A). We further study this oxide using XPS to estimate oxide thickness and composition over a larger area (250 μm spot size) (FIG. 13, D, E, F). XPS scans of the tantalum film show two sharp lower binding energy peaks assigned to tantalum metal 4f_{7/2} and 4f_{5/2} orbitals (lower binding energy to higher binding energy, respectively), two peaks at higher binding energy corresponding to the same orbitals of Ta₂O₅, and two small 5p_{3/2} peaks corresponding to the metal and oxide, respectively. Assuming the mean free path of electrons in tantalum is 2 nm at 1480 eV, and only taking into account inelastic scattering, a thickness can be estimated by comparing the ratio of oxide to metal peak areas. This estimation is corroborated using angle-resolved XPS (ARXPS), where the angle was varied between sample and detector, changing the relative distances that the emitted photoelectrons travel through the metal and oxide layers to reach the detector (FIG. 13). This geometry is accounted for in our modeling, and the oxide thickness was extracted at different angles (FIG. 13C). The thickness estimation remains fairly consistent until higher angles, when other effects related to surface morphology or elastic scattering become more significant (FIG. 13C).

To investigate the variability of oxide thickness between devices, normal incidence XPS data is shown from three devices from different tantalum depositions with different surface cleaning fabrication procedures (FIG. 13D, E, F). In addition to variations in other fabrication steps, it is noted that the device shown in FIG. 13D was only solvent cleaned, and the devices in FIG. 13E and FIG. 13F were piranha cleaned. The peak shapes and ratio of oxide to metal peak area are highly consistent between all these devices, suggesting there is no appreciable change in oxide thickness or composition.

1.6.4 Sapphire-Tantalum Interface

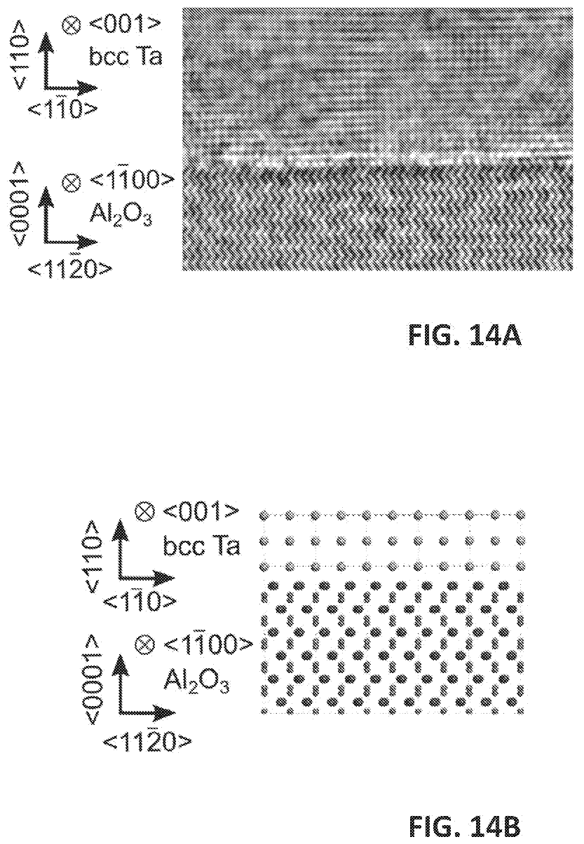

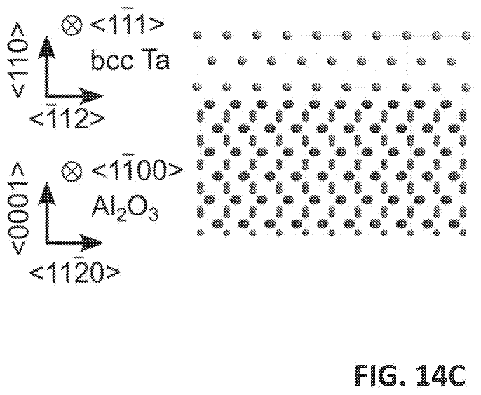

FIGS. 14A-C shows Tantalum-sapphire interface characterization. FIG. 14A Atomic resolution iDPC STEM image showing the interface between tantalum and sapphire with the image plane perpendicular to the <100> direction of tantalum. FIG. 14B shows an atomistic model of the ideal interface for the tantalum column orientation shown in FIG. 14A. FIG. 14C shows an atomistic model of the ideal interface for the tantalum column orientation shown in FIG. 3E. In both cases oxygen atoms are depicted in red, aluminum in green, and tantalum in blue.

For completeness, a iDPC STEM image is included showing the interface between sapphire and tantalum viewed from <11̅00> sapphire and <100> tantalum zone axes (FIG. 14A). Atomistic models for an ideal sapphire-tantalum interface are also proposed as shown in FIGS. 14B and C, as a starting point for future studies on the impact of sapphire surface morphology on heteroepitaxial growth.

1.6.5 XPS, AFM, XRD Characterization

All XPS, AFM, and XRD data were acquired using tools in the Imaging and Analysis Center at Princeton University.

XPS was performed using a Thermo Fisher K-Alpha and X-Ray Spectrometer tool with a 250 μm spot size. The data shown in FIG. 3D, FIGS. 6C-6D, and FIGS. 13D, E, and F were obtained by collecting photoelectrons at normal incidence between sample and detector. The angle-resolved XPS (ARXPS) spectra shown in FIG. 13B were collected by changing the angle between sample and detector. All AFM images were taken with a Bruker Dimension Icon3 tool operating in tapping mode (AFM tip from Oxford Instruments Asylum Research, part number AC160TS-R3, resonance frequency 300 kHz). The XRD spectrum shown in FIG. 9 was collected with a Bruker D8 Discover X-Ray Diffractometer configured with Bragg-Brentano optics. Two 0.6 mm slits were inserted before the sample, and a 0.1 mm slit was placed before the detector.

1.6.6 Electron Microscopy Characterization

SEM and STEM images were also collected at the Imaging and Analysis Center at Princeton University. STEM thin lamellae (thickness: 70-1300 nm) were prepared by focused ion beam cutting via a FEI Helios NanoLab 600 dual beam system (FIB/SEM). All the thin samples for experiments were polished by a 2 keV Ga ion beam to minimize the surface damage caused by the high-energy ion beam. Conventional STEM imaging, iDPC, atomic-resolution HAADF-STEM imaging and atomic-level EDS mapping were performed on a double Cs-corrected Titan Cubed Themis 300 STEM equipped with an X-FEG source operated at 300 kV and a super-X energy dispersive spectrometry (super-X EDS) system.

Lithography and etching process development SEM images were collected with a FEI Verios 460XHR SEM and a FEI Quanta 200 Environmental SEM. Various tilt angles, working distances, and chamber pressures were used to eliminate charging effects.

1.7 CPMG

To reduce the devices' low-frequency noise sensitivity a sequence of π-pulses were. Each pulse had a Gaussian envelope with σ around 20-50 ns and was truncated at ±2σ. Due to the large number of sequential pulses, it was found that reducing gate error through frequent calibration was important.

FIGS. 15A-B show CPMG noise spectrum of Device 11c. FIG. 15A shows T_{2,CPMG} as an increasing number of pulses reduce the qubit's sensitivity to low-frequency noise. FIG. 15B shows noise power spectral density, following. The red dashed line indicates a fit by eye to A/f^{α}+B where α=0.7, A=2e6s⁻¹, and B=3e2s⁻¹. Our signal-to-noise ratio is significantly worse, as the overall delay time between initial excitation and measurement increases. For clarity, only delays spanning up to approximately T₁ were included. For simplicity it is assumed the gates are instantaneous.

A noise power spectral density was found that is well fit by A/f^{α}+B with α=0.7.

1.8 Fitting Procedure

Our transmon T₁ data was fit to f(Δt)=e^{-Δt/T}^{₁}, where T₁ is a fit parameter and the function represents the population in the excited state. Any T₂ data taken with fringes was fit to f(Δt)=0.5e^{-Δt\T}^{_{2R}} cos(2πΔtδ+Ø₀)+0.5 where T2R, δ, and 00 are fit parameters. For echo and CPMG experiments, T₂ data was fit with a stretched exponential, f(Δt)=0.5e^{-(Δt\T}^{_{2R}}⁾^{ⁿ}+0.5, where T2 and n are fit parameters. If n<1, the data is refit to a pure exponential.

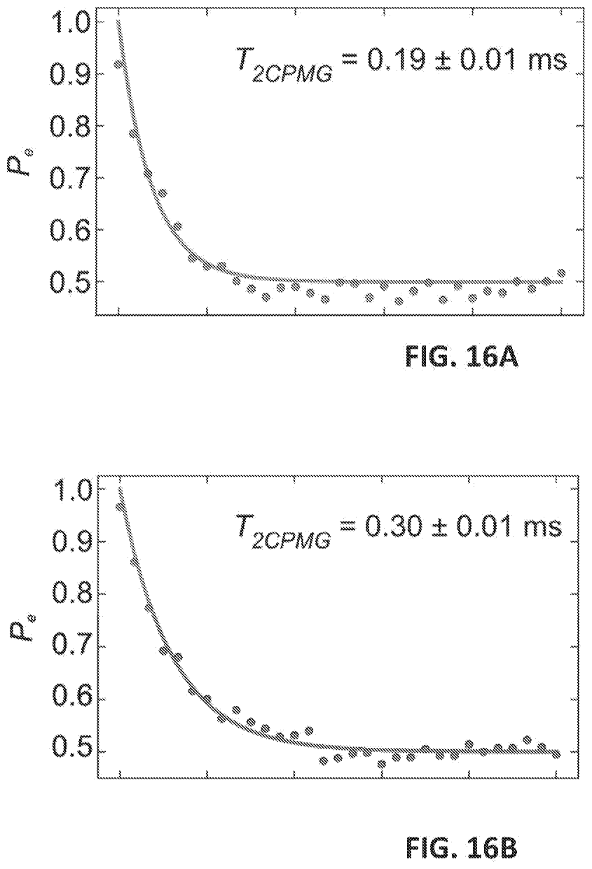

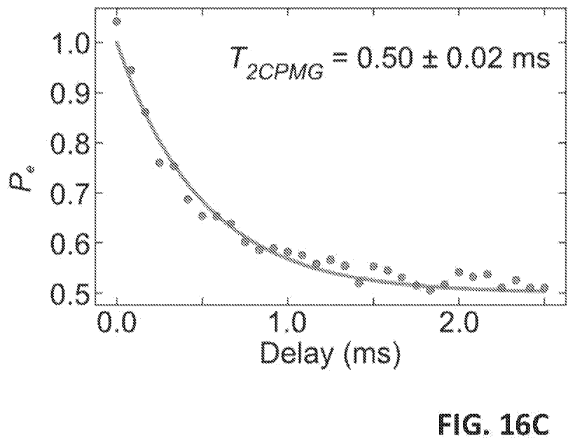

FIGS. 16A-C show CPMG traces. FIGS. 16A-C shows a representative decay for a low, average, and high value of T2,CPMG for the data shown in FIG. 2A. FIG. 16A shows a low T_{2,CPMG} trace from the data in FIG. 2A. FIG. 16B shows a middle T_{2,CPMG} trace from the data in FIG. 2A. FIG. 16C shows a low T_{2,CPMG} trace from the data in FIG. 2A. All three traces were fit to a stretched exponential with the exponent constrained to be larger than one. In time sequences, data traces with obvious abnormalities or poor fits as measured by root-mean-square error are discarded.

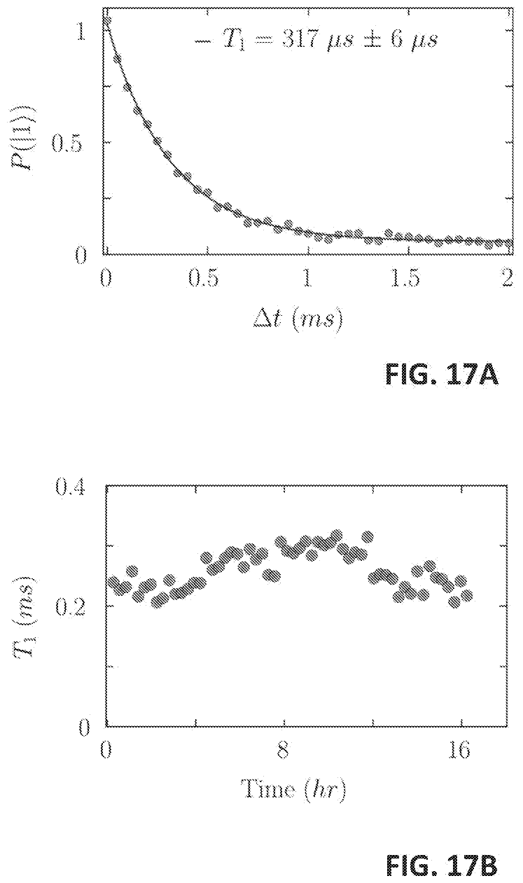

FIGS. 17A-B show coherence for a 2D transmon with alpha-TA and high purity substrate. Measurement of Relaxation time shows T1=317 μs from an example device.

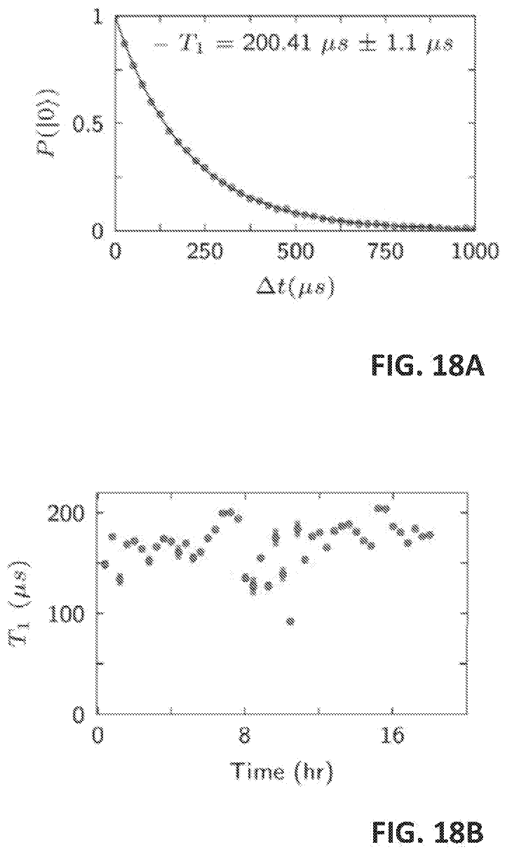

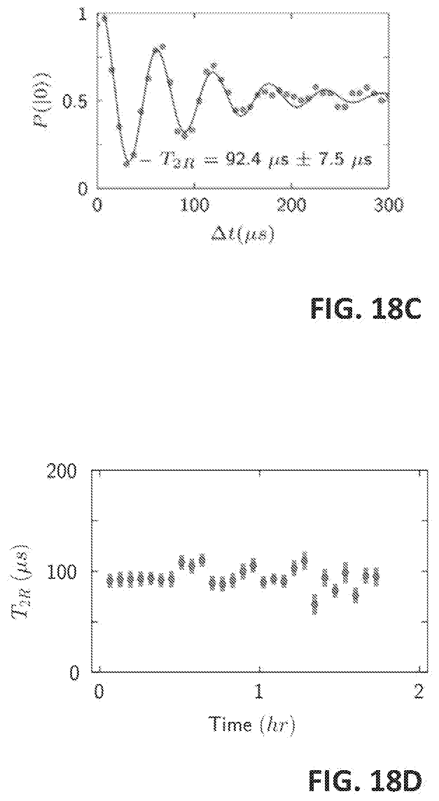

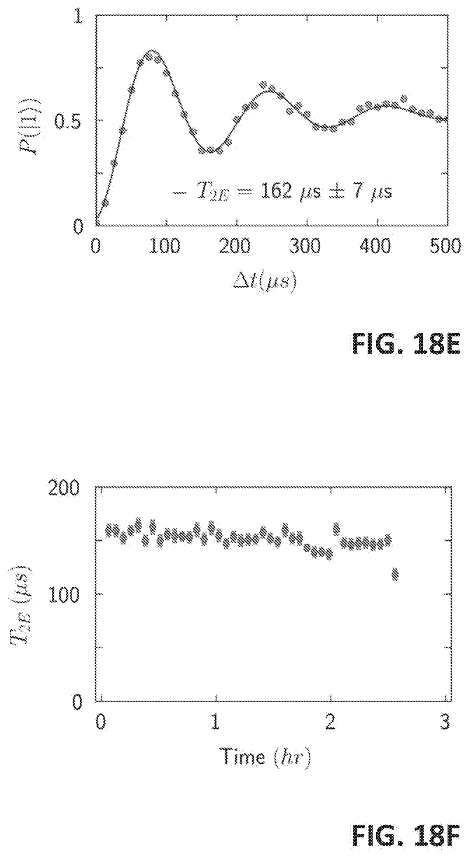

FIGS. 18A-F show coherence data from additional example 2D transmons. FIG. 18A-B shows data for an example transmon device. FIG. 18C-D shows coherence data for another example transmon device. FIG. 18E-F shows data for yet another example transmon device.

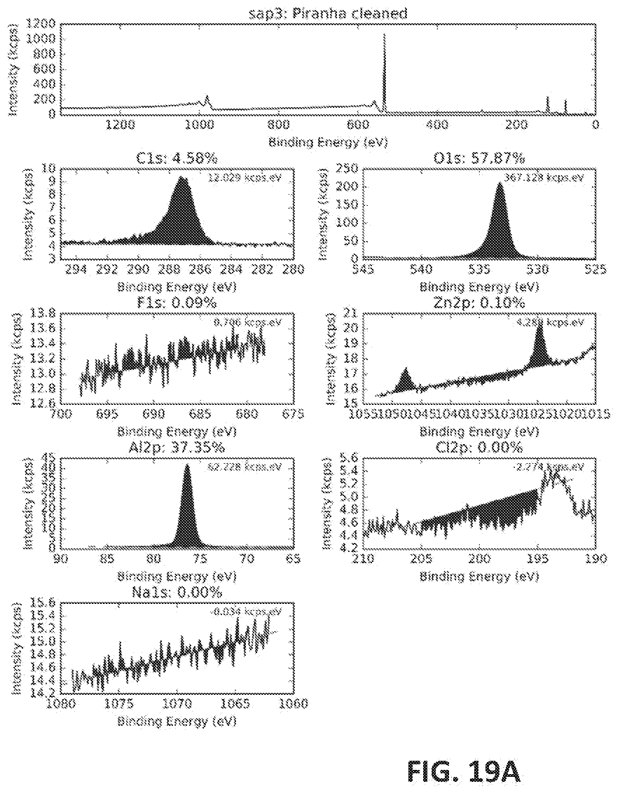

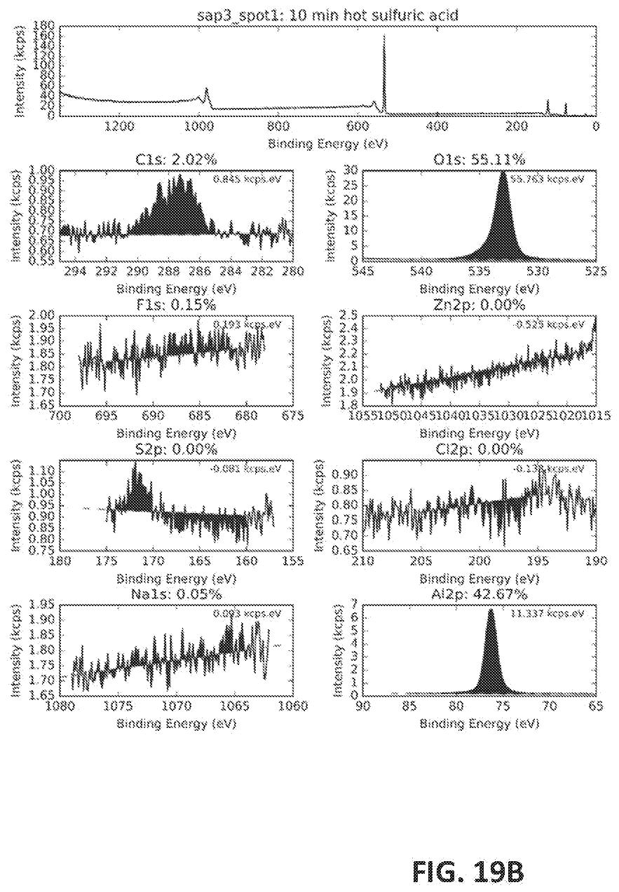

FIGS. 19A-B show preparation of pure substrate surfaces by polishing contamination. FIG. 19A shows XPS results of sapphire after performing a piranha 2:1 for 20 minutes. FIG. 19B shows results after applying sulfuric acid. Contamination was observed from the lap used to polish the wafers. In this case ZN (see Zn2p peak), through other metals could be used. A substrate with a pristine surface may be created by etching the top layer away with a hot sulfuric acid etch. The Zn2p peak is absent after this etch. Sulfuric acid also removes any subsurface damage.

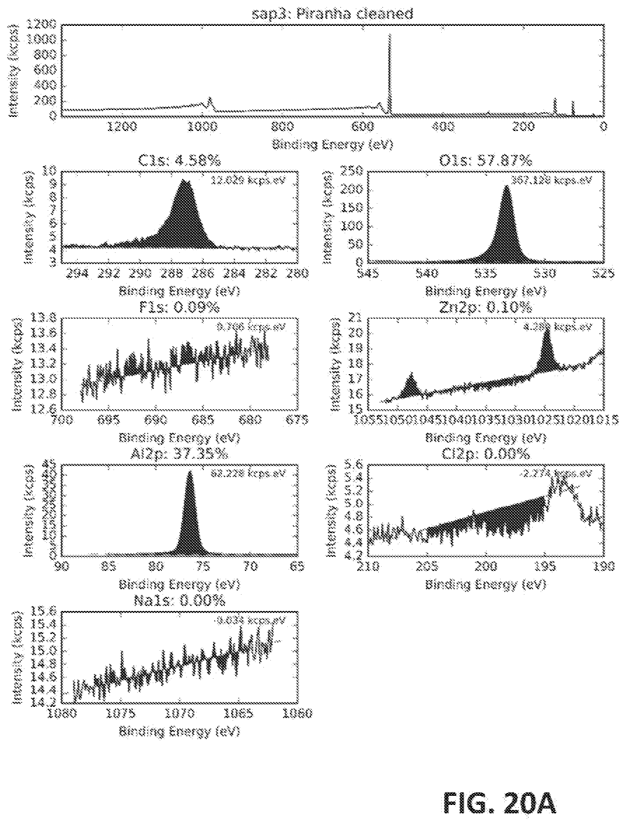

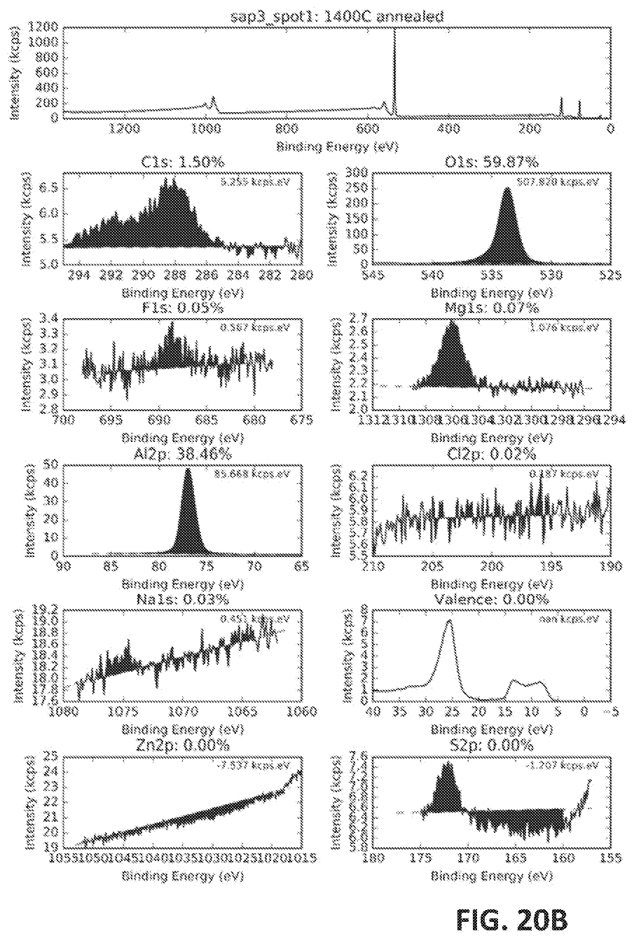

FIGS. 20A-B show preparation of pure substrates by annealing. FIG. 20A shows results after applying sulfuric acid before annealing. FIG. 20B shows results after applying sulfuric acid and after annealing. There is some sulfur observed on the surface after etching. We create a surface by annealing at high temperature (1400C).

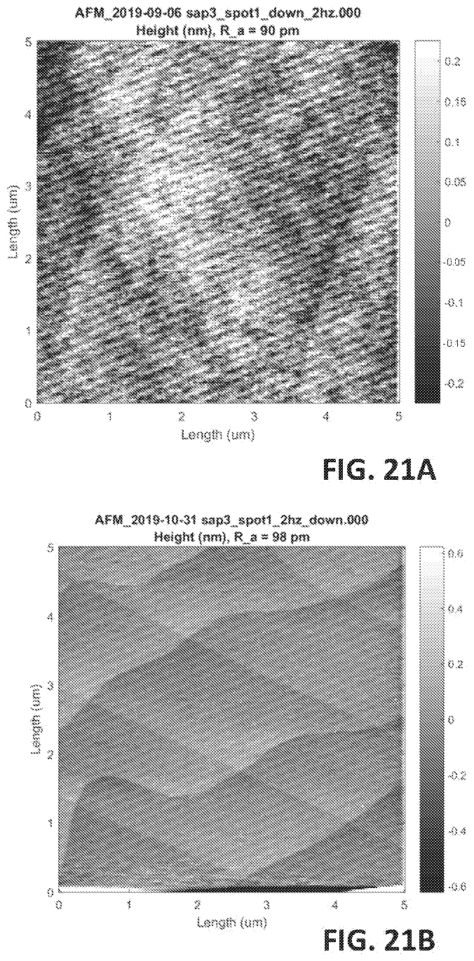

FIGS. 21A-B show results of surfaces before and after annealing. FIG. 21A shows results after sulfuric acid before annealing. FIG. 21B shows results after sulfuric acid and after annealing. Very smooth surfaces are observed in AFM after the sulfuric acid but before an anneal step; these are improved to atomically smooth surfaces after a 1400C anneal.

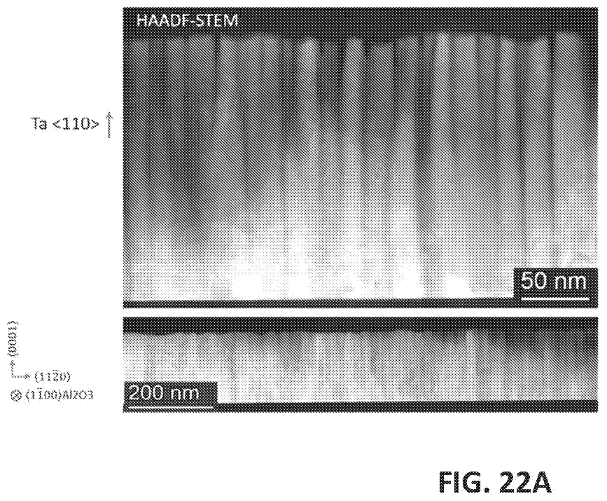

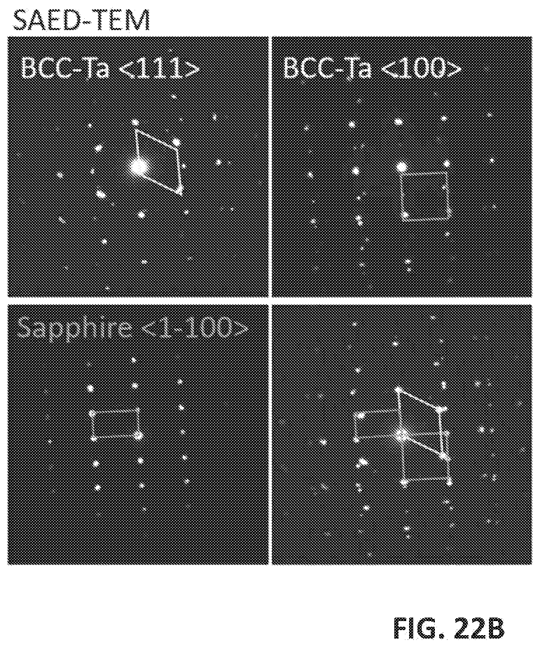

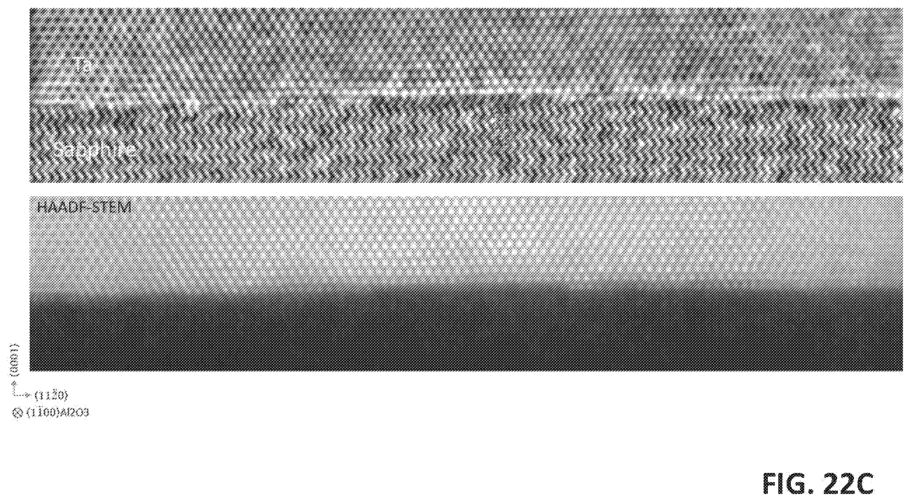

FIGS. 22A-C show direct imaging of alpha-TA films with TEM. FIG. 22A shows an image of an alpha-Ta film. FIG. 22B shows a selected area electron diffraction (SAED) of the alpha-Ta film. FIG. 22C shows direct imaging the interface between an alpha-Ta film and sapphire with TEM. of alpha-Ta films with TEM. We can directly observe the crystal structure of alpha-TA by HR TEM, which demonstrates the creation of a BCC (alpha phase) Ta film that is quasi-epitaxial on a sapphire substrate.

The disclosure may comprise at least the following aspects.

Aspect 1. A device comprising, consisting of, or consisting essentially of: a substrate having a first surface; and a patterned layer adjacent the substrate and comprising tantalum in an alpha phase, wherein the patterned layer forms at least a part of a structure for storing a quantum state.

Aspect 2. The device of Aspect 1, wherein the patterned layer forms at least a portion of a circuit component comprising the tantalum in the alpha phase.

Aspect 3. The device of Aspect 2, wherein the circuit component comprises one or more of a capacitor, an inductor, or a Josephson junction.

Aspect 4. The device of any one of Aspects 1-3, wherein the patterned layer forms one or more electrical circuit components configured to store the quantum state based on enabling non-harmonic energy levels for forming qubit states.

Aspect 5. The device of any one of Aspects 1-4, wherein the structure comprises one or more of a qubit, a transmon qubit, a X mon qubit, a three-dimensional transmon qubit, a fluxionium qubit, or a zero-pi qubit.

Aspect 6. The device of any one of Aspects 1-5, further comprising one or more additional layers that form one or more electric components, wherein the patterned layer and the one or more additional layers form an electrical circuit configured to form energy levels for storing the quantum state.

Aspect 7. The device of any one of Aspects 1-6, wherein the one or more additional layers comprise a Josephson junction.

Aspect 8. The device of any one of Aspects 1-7, wherein a relaxation time of the quantum state comprises one or more of at least 150 μs, at least 200 μs, or at least 300 μs.

Aspect 9. The device of any one of Aspects 1-8, wherein a relaxation time of the quantum state is in a range of one or more of 150 μs to 317 μs or 200 μs to 317 μs.

Aspect 10. The device of any one of Aspects 1-9, wherein the substrate comprises one or more of sapphire or silicon.

Aspect 11. The device of any one of Aspects 1-10, wherein the first surface contains least one of: less than 6 atomic percent carbon as measured by X-ray photoelectron spectroscopy (XPS) or less than 0.1 atomic percent zinc as measured by X-ray photoelectron spectroscopy (XPS).

Aspect 12. The device of any one of Aspects 1-11, wherein the first surface has an average roughness less than 0.1 nm as measured by atomic force microscopy.

Aspect 13. The device of any one of Aspects 1-12, wherein the structure is free of niobium.

Aspect 14. The device of any one of Aspects 1-13, wherein the patterned layer forms a plurality of superconducting qubits.

Aspect 15. The device of any one of Aspects 1-14, wherein the tantalum in the alpha phase comprises tantalum having a body-centered cubic crystal structure.

Aspect 16. A method comprising, consisting of, or consisting essentially of: providing a substrate having a first surface; and forming a patterned layer adjacent the substrate and comprising tantalum in an alpha phase, wherein the patterned layer forms at least a part of a structure for storing a quantum state.

Aspect 17. The method of Aspect 16, wherein the forming the patterned layer comprises forming a layer of tantalum in the alpha phase and patterning the layer of tantalum using an etching process.

Aspect 18. The method of Aspect 17, wherein the etching process comprises a wet etch process.

Aspect 19. The method of any one of Aspects 16-18, further comprising treating one or more of the substrate and a tantalum film used to form the patterned layer by at least one of: cleaning an exposed surface of the tantalum film with a piranha cleaning solution, or treating the exposed surface of the tantalum film with an oxygen plasma descum.

Aspect 20. The method of any one of Aspects 16-18, further comprising treating the first surface of the substrate by at least one of etching with a heated sulfuric acid etch, cleaning the first surface with a piranha cleaning solution, cleaning by oxygen plasma, or annealing the first surface at an annealing temperature.

Aspect 21. The method of Aspect 20, wherein the annealing temperature one or more of: in a range of 1300° C. to 1500° C., or high enough to cause the sapphire surface to form atomic steps, as measured by atomic force microscopy.

Aspect 22. The method of any one of Aspects 20-21, further comprising providing in situ heating during a sputtering-deposition of tantalum to form a film of tantalum on the alpha phase.

Aspect 23. The method of any one of Aspects 16-22, wherein forming the patterned layer comprises performing a sputtering-deposition of tantalum at a predetermined deposition temperature onto the first surface after applying an annealing process to the first surface.

Aspect 24. The method of any one of Aspects 16-23, further comprising polishing the substrate and etching the polished substrate with a heated sulfuric acid etch.

Aspect 25. The method of any one of Aspects 16-24, wherein the substrate is sapphire.

Aspect 26. The method of any one of Aspects 16-25, wherein the structure is free of niobium.

Aspect 27. The method of any one of Aspects 16-26, wherein forming the patterned layer comprises forming at least a portion of a circuit component comprising the tantalum in the alpha phase.

Aspect 28. The method of Aspect 27, wherein the circuit component comprises one or more of a capacitor, an inductor, or a Josephson junction.

Aspect 29. The method of any one of Aspects 16-28, wherein forming the patterned layer comprising forming one or more electrical circuit components configured to cause the quantum state to be stored based on enabling non-harmonic energy levels for forming qubit states.

Aspect 30. The method of any one of Aspects 16-29, wherein the structure comprises one or more of a qubit, a transmon qubit, a X mon qubit, a three-dimensional transmon qubit, a fluxionium qubit, or a zero-pi qubit.

Aspect 31. The method of any one of Aspects 16-30, further comprising forming one or more additional layers that form one or more electric components, wherein the patterned layer and the one or more additional layers form an electrical circuit configured to form energy levels for storing the quantum state.

Aspect 32. The method of Aspect 31, wherein the one or more additional layers comprise a Josephson junction.

Aspect 33. The method of any one of Aspects 16-32, wherein a relaxation time of the quantum state comprises one or more of at least 150 μs, at least 200 μs, or at least 300 μs.

Aspect 34. The method of any one of Aspects 16-33, wherein a relaxation time of the quantum state is in a range of one or more of 150 μs to 317 μs or 200 μs to 317 μs.

Aspect 35. The method of any one of Aspects 16-34, wherein the tantalum in the alpha phase comprises tantalum having a body-centered cubic crystal structure.

Aspect 36. The method of any one of Aspects 16-35, wherein the substrate comprises a sapphire substrate having a first surface substantially devoid of zinc contamination.

Aspect 37. A system comprising, consisting of, or consisting essentially of a plurality of superconducting qubits according to the device of any of claims 1-15.

Aspect 38. A method comprising, consisting of, or consisting essentially of storing quantum information using one or more devices according to any of claims 1-15.

It is to be understood that the methods and systems are not limited to specific methods, specific components, or to particular implementations. It is also to be understood that the terminology used herein is for the purpose of describing particular embodiments only and is not intended to be limiting.

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other components, integers or steps. “Exemplary” means “an example of” and is not intended to convey an indication of a preferred or ideal embodiment. “Such as” is not used in a restrictive sense, but for explanatory purposes.

Components are described that may be used to perform the described methods and systems. When combinations, subsets, interactions, groups, etc., of these components are described, it is understood that while specific references to each of the various individual and collective combinations and permutations of these may not be explicitly described, each is specifically contemplated and described herein, for all methods and systems. This applies to all aspects of this application including, but not limited to, operations in described methods. Thus, if there are a variety of additional operations that may be performed it is understood that each of these additional operations may be performed with any specific embodiment or combination of embodiments of the described methods.

As will be appreciated by one skilled in the art, the methods and systems may take the form of an entirely hardware embodiment, an entirely software embodiment, or an embodiment combining software and hardware aspects. Furthermore, the methods and systems may take the form of a computer program product on a computer-readable storage medium having computer-readable program instructions (e.g., computer software) embodied in the storage medium. More particularly, the present methods and systems may take the form of web-implemented computer software. Any suitable computer-readable storage medium may be utilized including hard disks, CD-ROMs, optical storage devices, or magnetic storage devices.

Embodiments of the methods and systems are described herein with reference to block diagrams and flowchart illustrations of methods, systems, apparatuses and computer program products. It will be understood that each block of the block diagrams and flowchart illustrations, and combinations of blocks in the block diagrams and flowchart illustrations, respectively, may be implemented by computer program instructions. These computer program instructions may be loaded on a general-purpose computer, special-purpose computer, or other programmable data processing apparatus to produce a machine, such that the instructions which execute on the computer or other programmable data processing apparatus create a means for implementing the functions specified in the flowchart block or blocks.

These computer program instructions may also be stored in a computer-readable memory that may direct a computer or other programmable data processing apparatus to function in a particular manner, such that the instructions stored in the computer-readable memory produce an article of manufacture including computer-readable instructions for implementing the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

The various features and processes described above may be used independently of one another, or may be combined in various ways. All possible combinations and sub-combinations are intended to fall within the scope of this disclosure. In addition, certain methods or process blocks may be omitted in some implementations. The methods and processes described herein are also not limited to any particular sequence, and the blocks or states relating thereto may be performed in other sequences that are appropriate. For example, described blocks or states may be performed in an order other than that specifically described, or multiple blocks or states may be combined in a single block or state. The example blocks or states may be performed in serial, in parallel, or in some other manner. Blocks or states may be added to or removed from the described example embodiments. The example systems and components described herein may be configured differently than described. For example, elements may be added to, removed from, or rearranged compared to the described example embodiments.

It will also be appreciated that various items are illustrated as being stored in memory or on storage while being used, and that these items or portions thereof may be transferred between memory and other storage devices for purposes of memory management and data integrity. Alternatively, in other embodiments, some or all of the software modules and/or systems may execute in memory on another device and communicate with the illustrated computing systems via inter-computer communication. Furthermore, in some embodiments, some or all of the systems and/or modules may be implemented or provided in other ways, such as at least partially in firmware and/or hardware, including, but not limited to, one or more application-specific integrated circuits (“ASICs”), standard integrated circuits, controllers (e.g., by executing appropriate instructions, and including microcontrollers and/or embedded controllers), field-programmable gate arrays (“FPGAs”), complex programmable logic devices (“CPLDs”), etc. Some or all of the modules, systems, and data structures may also be stored (e.g., as software instructions or structured data) on a computer-readable medium, such as a hard disk, a memory, a network, or a portable media article to be read by an appropriate device or via an appropriate connection. The systems, modules, and data structures may also be transmitted as generated data signals (e.g., as part of a carrier wave or other analog or digital propagated signal) on a variety of computer-readable transmission media, including wireless-based and wired/cable-based media, and may take a variety of forms (e.g., as part of a single or multiplexed analog signal, or as multiple discrete digital packets or frames). Such computer program products may also take other forms in other embodiments. Accordingly, the present invention may be practiced with other computer system configurations.

While the methods and systems have been described in connection with preferred embodiments and specific examples, it is not intended that the scope be limited to the particular embodiments set forth, as the embodiments herein are intended in all respects to be illustrative rather than restrictive.

It will be apparent to those skilled in the art that various modifications and variations may be made without departing from the scope or spirit of the present disclosure. Other embodiments will be apparent to those skilled in the art from consideration of the specification and practices described herein. It is intended that the specification and example figures be considered as exemplary only, with a true scope and spirit being indicated by the following claims.

What is claimed:

1. A device for forming a superconducting qubit, comprising:
a substrate having a first surface; and
a patterned layer adjacent the substrate and comprising tantalum in an alpha phase, wherein the patterned layer forms at least a part of a structure for storing a quantum state.

2. The device of claim 1, wherein the patterned layer forms at least a portion of a circuit component comprising the tantalum in the alpha phase.

3. The device of claim 2, wherein the circuit component comprises one or more of a capacitor, an inductor, or a Josephson junction.

4. The device of claim 1, wherein the patterned layer forms one or more electrical circuit components configured to store the quantum state based on enabling non-harmonic energy levels for forming qubit states.

5. The device of claim 1, wherein the structure comprises one or more of a qubit, a transmon qubit, a X mon qubit, a three-dimensional transmon qubit, a fluxionium qubit, or a zero-pi qubit.

6. The device of claim 1, further comprising one or more additional layers that form one or more electric components, wherein the patterned layer and the one or more additional layers form an electrical circuit configured to form energy levels for storing the quantum state.

7. The device of claim 6, wherein the one or more additional layers comprise a Josephson junction.

8. The device of claim 1, wherein a relaxation time of the quantum state comprises one or more of at least 150 μs, at least 200 μs, or at least 300 μs.

9. The device of claim 1, wherein a relaxation time of the quantum state is in a range of one or more of 150 μs to 317 μs or 200 μs to 317 μs.

10. The device of claim 1, wherein the substrate comprises one or more of sapphire or silicon.

11. The device of claim 1, wherein the first surface contains least one of: less than 6 atomic percent carbon as measured by X-ray photoelectron spectroscopy (XPS) or less than 0.1 atomic percent zinc as measured by X-ray photoelectron spectroscopy (XPS).

12. The device of claim 1, wherein the first surface has an average roughness less than 0.1 nm as measured by atomic force microscopy.

13. The device of claim 1, wherein the structure is free of niobium.

14. The device of claim 1, wherein the patterned layer forms a plurality of superconducting qubits.

15. The device of claim 1, wherein the tantalum in the alpha phase comprises tantalum having a body-centered cubic crystal structure.

16. A method for producing a superconducting qubit, comprising:
providing a substrate having a first surface; and
forming a patterned layer adjacent the substrate and comprising tantalum in an alpha phase, wherein the patterned layer forms at least a part of a structure for storing a quantum state.

17. The method of claim 16, wherein the forming the patterned layer comprises forming a layer of tantalum in the alpha phase and patterning the layer of tantalum using an etching process.

18. The method of claim 17, wherein the etching process comprises a wet etch process.

19. The method of claim 16, further comprising treating one or more of the substrate and a tantalum film used to form the patterned layer by at least one of: cleaning an exposed surface of the tantalum film with a piranha cleaning solution, or treating the exposed surface of the tantalum film with an oxygen plasma descum.

20. The method of claim 16, further comprising treating the first surface of the substrate by at least one of etching with a heated sulfuric acid etch, cleaning the first surface with a piranha cleaning solution, cleaning by oxygen plasma, or annealing the first surface at an annealing temperature.

21. The method of claim 20, wherein the annealing temperature one or more of: in a range of 1300° C. to 1500° C., or high enough to cause the sapphire surface to form atomic steps, as measured by atomic force microscopy.

22. The method of claim 20, further comprising providing in situ heating during a sputtering-deposition of tantalum to form a film of tantalum on the alpha phase.

23. The method of claim 16, wherein forming the patterned layer comprises performing a sputtering-deposition of tantalum at a predetermined deposition temperature onto the first surface after applying an annealing process to the first surface.

24. The method of claim 16, further comprising polishing the substrate and etching the polished substrate with a heated sulfuric acid etch.

25. The method of claim 16, wherein the substrate is sapphire.

26. The method of claim 16, wherein the structure is free of niobium.

27. The method of claim 16, wherein forming the patterned layer comprises forming at least a portion of a circuit component comprising the tantalum in the alpha phase.

28. The method of claim 27, wherein the circuit component comprises one or more of a capacitor, an inductor, or a Josephson junction.

29. The method of claim 16, wherein forming the patterned layer comprising forming one or more electrical circuit components configured to cause the quantum state to be stored based on enabling non-harmonic energy levels for forming qubit states.

30. The method of claim 16, wherein the structure comprises one or more of a qubit, a transmon qubit, a X mon qubit, a three-dimensional transmon qubit, a fluxionium qubit, or a zero-pi qubit.

31. The method of claim 16, further comprising forming one or more additional layers that form one or more electric components, wherein the patterned layer and the one or more additional layers form an electrical circuit configured to form energy levels for storing the quantum state.

32. The method of claim 31, wherein the one or more additional layers comprise a Josephson junction.

33. The method of claim 16, wherein a relaxation time of the quantum state comprises one or more of at least 150 μs, at least 200 μs, or at least 300 μs.

34. The method of claim 16, wherein a relaxation time of the quantum state is in a range of one or more of 150 μs to 317 μs or 200 μs to 317 μs.

35. The method of claim 16, wherein the tantalum in the alpha phase comprises tantalum having a body-centered cubic crystal structure.

36. The method of claim 16, wherein the substrate comprises a sapphire substrate having a first surface substantially devoid of zinc contamination.
